(19) United States
(12) Patent Application Publication
(10) Pub. No.: US 2025/0317237 A1
(43) Pub. Date: Oct. 9, 2025

(54) DATA TRANSMISSION METHOD AND APPARATUS

(71) Applicant: HUAWEI TECHNOLOGIES CO., LTD., Shenzhen (CN)

(72) Inventors: Ke LIU, Hangzhou (CN); Huazi ZHANG, Hangzhou (CN); Jiajie TONG, Hangzhou (CN); Xianbin WANG, Hangzhou (CN); Jun WANG, Hangzhou (CN)

(21) Appl. No.: 19/241,817

(22) Filed: Jun. 18, 2025

Related U.S. Application Data
(63) Continuation of application No. PCT/CN2022/139857, filed on Dec. 19, 2022.

(51) Int. Cl. H04L 1/00; H03M 13/11

(52) U.S. Cl. CPC H04L 1/0057; H03M 13/1102

(57) ABSTRACT

This application provides a data transmission method and an apparatus. A first device determines a target lifting size based on a length of an information bit corresponding to to-be-transmitted data and an information column quantity of an LDPC base graph, where the target lifting size is in at least one of m lifting size sets, one lifting size set includes a lifting size corresponding to at least one of n bases, the m lifting size sets include lifting sizes corresponding to the n bases, a lifting size corresponding to an i^{th} base aᵢ in the n bases is determined based on a product of aᵢ and an integer power of 2, n is greater than m, and aᵢ is a positive integer. The first device determines, from m shifting value sets, a first shifting value set corresponding to the target lifting size.

### CROSS-REFERENCE TO RELATED APPLICATIONS

This application is a continuation of International Application No. PCT/CN 2022/139857, filed on Dec. 19, 2022, the disclosure of which is hereby incorporated by reference in its entirety.

### TECHNICAL FIELD

This application relates to the communication field, and more specifically, to a data transmission method and an apparatus.

### BACKGROUND

A low-density parity-check code (low-density parity-check code, LDPC) is a channel coding scheme that is very close to a Shannon (Shannon) limit, and has features of good performance, low complexity, and a flexible structure. The LDPC code is a research hotspot in the field of channel coding in recent years, and has been widely used in fields such as deep space communication, optical fiber communication, and satellite digital video and audio broadcasting. Currently, the LDPC code has been determined by the 3rd generation partnership project (3rd generation partnership project, 3GPP) as a 5th generation (5th generation, 5G) data channel coding scheme.

In a manner of performing encoding by using the LDPC code, encoding is performed by using a generator matrix or a check matrix, and the generator matrix is generated based on the check matrix. The check matrix is generated by extending 1 in an LDPC base graph into a cyclic shift matrix by using a lifting size (lifting size, LS) and a shifting value (shifting value, SV). In an existing technical solution, each group of lifting sizes corresponds to one group of shifting values, and a transmit end and a receive end for data transmission need to store a plurality of groups of shifting values. As a result, a quantity of shifting values that need to be stored is relatively large, and an LDPC cyclic shift network of a quasi-cyclic (qusai-cyclic, QC) structure (QC LDPC shift network, QSN) is complex.

### SUMMARY

This application provides a data transmission method and an apparatus, to reduce a quantity of shifting values that need to be stored, thereby reducing complexity of a QSN.

According to a first aspect, a data transmission method is provided. The method may be performed by a chip or a chip system on a terminal device side or a network device side. The method includes: A first device determines a target lifting size based on a length of an information bit corresponding to to-be-transmitted data and an information column quantity of a low-density parity-check code LDPC base graph, where the target lifting size is in at least one of m lifting size sets, one lifting size set includes a lifting size corresponding to at least one of n bases, the m lifting size sets include lifting sizes corresponding to the n bases, a lifting size corresponding to an i^{th} base aᵢ in the n bases is determined based on a product of aᵢ and an integer power of 2, n is greater than m, and aᵢ is a positive integer; the first device determines a first shifting value set corresponding to the target lifting size, where the first shifting value set is in m shifting value sets; and the first device sends the to-be-transmitted data based on the target lifting size and the first shifting value set.

Based on the foregoing technical solution, one of the m lifting size sets stored in the first device and a second device includes a lifting size corresponding to one or more of the n bases, the m lifting size sets correspond to m shifting value sets, and m is less than n. Compared with that n shifting value sets corresponding to the n bases are supported, in this embodiment of this application, a transmit end (the first device) and a receive end (the second device) for data transmission need to support only the m shifting value sets. Therefore, a quantity of shifting values that need to be stored can be reduced, and complexity of a QSN can be reduced.

With reference to the first aspect, in some implementations of the first aspect, the m shifting value sets are in one-to-one correspondence with the m lifting size sets.

With reference to the first aspect, in some implementations of the first aspect, a j^{th} shifting value set in the m shifting value sets belongs to {tⱼ,1+tⱼ,2+tⱼ, . . . , H₍ⱼ₎+tⱼ−1}, H₍ⱼ₎ is less than a maximum value of lifting sizes in a j^{th} lifting size set corresponding to the j^{th} shifting value set, tⱼ is an integer, and H₍ⱼ₎ is a positive integer.

Based on the foregoing solution, because H₍ⱼ₎ is less than the maximum value Zₘₐₓ₍ⱼ₎ of the lifting sizes in the j^{th} lifting size set corresponding to the j^{th} shifting value set, where Zₘₐₓ₍ⱼ₎=aⱼ×2^{k}^{ₘₐₓ₍ⱼ₎}, a value range of a shifting value set that needs to be supported by the first device and the second device is less than a value range of [0, 1, 2, . . . , aⱼ×2^{k}^{ₘₐₓ₍ⱼ₎}−1]. Therefore, a quantity of shifting values that need to be stored can be further reduced, and complexity of a QSN can be further reduced.

With reference to the first aspect, in some implementations of the first aspect, a difference between different H₍ⱼ₎ corresponding to the m shifting value sets is less than or equal to a first preset threshold. Values of H₍ⱼ₎ corresponding to different shifting value sets are relatively consistent, so that complexity of QSN hardware corresponding to the different shifting value sets is relatively consistent.

With reference to the first aspect, in some implementations of the first aspect, the method further includes: The first device sends indication information to the second device, where the indication information indicates the target lifting size and/or the first shifting value set.

According to a second aspect, a data transmission method is provided. The method may be performed by a chip or a chip system on a terminal device side or a network device side. The method includes: A second device receives encoded data from a first device, and determines a target lifting size based on a length of an information bit corresponding to the encoded data and an information column quantity of an LDPC base graph, where the target lifting size is in at least one of m lifting size sets, one lifting size set includes a lifting size corresponding to at least one of n bases, the m lifting size sets include lifting sizes corresponding to the n bases, a lifting size corresponding to an i^{th} base aᵢ in the n bases is determined based on a product of aᵢ and an integer power of 2, n is greater than m, and aᵢ is a positive integer; the second device determines a first shifting value set corresponding to the target lifting size, where the first shifting value set is in m shifting value sets; and the second device decodes the encoded data based on the target lifting size and the first shifting value set.

The method provided in the second aspect is a receive end method corresponding to the first aspect. For beneficial effects thereof, directly refer to those of the first aspect.

With reference to the second aspect, in some implementations of the second aspect, the m shifting value sets are in one-to-one correspondence with the m lifting size sets.

With reference to the second aspect, in some implementations of the second aspect, a j^{th} shifting value set in the m shifting value sets belongs to {tⱼ,1+tⱼ,2+tⱼ, . . . , H₍ⱼ₎+tⱼ−1}, H₍ⱼ₎ is less than a maximum value of lifting sizes in a j^{th} lifting size set corresponding to the j^{th} shifting value set, tⱼ is an integer, and H₍ⱼ₎ is a positive integer.

With reference to the second aspect, in some implementations of the second aspect, a difference between different H₍ⱼ₎ corresponding to the m shifting value sets is less than or equal to a first preset threshold.

With reference to the second aspect, in some implementations of the second aspect, the method further includes: The second device receives indication information from the first device, where the indication information indicates the target lifting size and/or the first shifting value set.

According to a third aspect, a data transmission method is provided. The method may be performed by a chip or a chip system on a terminal device side or a network device side. The method includes: A first device determines a target lifting size based on a length of an information bit corresponding to to-be-transmitted data, an information column quantity of an LDPC base graph, and n bases, where the target lifting size is in a plurality of lifting sizes corresponding to the n bases, a lifting size corresponding to an i^{th} base aᵢ in the n bases is aᵢ×2^{k}^{ᵢ}, aᵢ is a positive integer, and kᵢ is an integer greater than or equal to zero; the first device determines a first shifting value set corresponding to the target lifting size, where the first shifting value set is in n shifting value sets, the n shifting value sets are in one-to-one correspondence with the n bases, an i^{th} shifting value set in the n shifting value sets belongs to {tᵢ, 1+tᵢ, 2+tᵢ, . . . , Uᵢ+tᵢ−1}, Uᵢ is less than or equal to a second preset threshold, tᵢ is an integer, and Uᵢ is a positive integer; and the first device sends the to-be-transmitted data to a second device based on the target lifting size and the first shifting value set.

Based on the foregoing technical solution, because there is no limitation on a threshold of kᵢ corresponding to a basis, there is no maximum value or threshold for a lifting size corresponding to the basis. When the length of the information bit corresponding to the to-be-transmitted data is relatively large, the determined target lifting size is also relatively large, so that data of more information bits can be transmitted. In addition, when the length of the information bit corresponding to the to-be-transmitted data increases to a specific extent, a value of a shifting value in the first shifting value set corresponding to the target lifting size does not increase, and a value range of the shifting value in the first shifting value set does not increase. Therefore, when a code length of an LDPC code increases to a specific extent, complexity of a QSN no longer increases with an increase in the code length of the LDPC code, and an area gain of an encoding chip or a decoding chip gradually increases with an increase in the code length of the LDPC code.

With reference to the third aspect, in some implementations of the third aspect, that a first device determines a target lifting size based on a length of an information bit corresponding to to-be-transmitted data, an information column quantity of an LDPC base graph, and n bases includes: The first device determines, based on the length of the information bit corresponding to the to-be-transmitted data, the information column quantity of the LDPC base graph, and the n bases, n candidate lifting sizes corresponding to the n bases, where lengths of information bits of LDPC codes corresponding to the n candidate lifting sizes are greater than or equal to the length of the information bit corresponding to the to-be-transmitted data; and the first device determines a smallest candidate lifting size in the n candidate lifting sizes as the target lifting size.

The smallest candidate lifting size in the n candidate lifting sizes is determined as the target lifting size, so that a quantity of shortened bits can be reduced, and decoding performance of a receive end (the second device) can be improved.

With reference to the third aspect, in some implementations of the third aspect, that a first device determines a target lifting size based on a length of an information bit corresponding to to-be-transmitted data, an information column quantity of an LDPC base graph, and n bases includes: The first device determines the target lifting size based on the length of the information bit corresponding to the to-be-transmitted data, the information column quantity of the LDPC base graph, the n bases, and a lifting size threshold.

With reference to the third aspect, in some implementations of the third aspect, that the first device determines the target lifting size based on the length of the information bit corresponding to the to-be-transmitted data, the information column quantity of the LDPC base graph, the n bases, and a lifting size threshold includes: The first device determines, based on the length of the information bit corresponding to the to-be-transmitted data, the information column quantity of the LDPC base graph, and the n bases, n candidate lifting sizes corresponding to the n bases, where lengths of information bits of LDPC codes corresponding to the n candidate lifting sizes are greater than or equal to the length of the information bit corresponding to the to-be-transmitted data; and if a smallest candidate lifting size in the n candidate lifting sizes is less than or equal to the lifting size threshold, the first device determines the smallest candidate lifting size as the target lifting size; or if the smallest candidate lifting size in the n candidate lifting sizes is greater than the lifting size threshold, the first device determines the lifting size threshold as the target lifting size.

With reference to the third aspect, in some implementations of the third aspect, a difference between different Uᵢ corresponding to the n shifting value sets is less than or equal to a third preset threshold. Values of Uᵢ corresponding to different shifting value sets are relatively consistent, so that complexity of QSN hardware corresponding to the different shifting value sets is relatively consistent.

With reference to the third aspect, in some implementations of the third aspect, the method further includes: The first device sends indication information to a second device, where the indication information indicates the target lifting size and/or the first shifting value set.

According to a fourth aspect, a data transmission method is provided. The method may be performed by a chip or a chip system on a terminal device side or a network device side. The method includes: A second device receives encoded data from a first device; the second device determines a target lifting size based on a length of an information bit corresponding to the encoded data, an information column quantity of an LDPC base graph, and n bases, where the target lifting size is in a plurality of lifting sizes corresponding to the n bases, a lifting size corresponding to an i^{th} base aᵢ in the n bases is aᵢ×2^{k}^{ᵢ}, aᵢ is a positive integer, and kᵢ is an integer greater than or equal to zero; the second device determines a first shifting value set corresponding to the target lifting size, where the first shifting value set is in n shifting value sets, the n shifting value sets are in one-to-one correspondence with the n bases, an i^{th} shifting value set in the n shifting value sets belongs to {tᵢ, 1+tᵢ, 2+tᵢ, . . . , Uᵢ+tᵢ−1}, Uᵢ is less than or equal to a second preset threshold, tᵢ is an integer, and Uᵢ is a positive integer; and the second device decodes the encoded data based on the target lifting size and the first shifting value set.

The method provided in the fourth aspect is a receive end method corresponding to the third aspect. For beneficial effects thereof, directly refer to those of the third aspect.

With reference to the fourth aspect, in some implementations of the fourth aspect, that the second device determines a target lifting size based on a length of an information bit corresponding to the encoded data, an information column quantity of an LDPC base graph, and n bases includes: The second device determines, based on the length of the information bit corresponding to the encoded data, the information column quantity of the LDPC base graph, and the n bases, n candidate lifting sizes corresponding to the n bases, where lengths of information bits of LDPC codes corresponding to the n candidate lifting sizes are greater than or equal to the length of the information bit corresponding to the to-be-transmitted data; and the second device determines a smallest candidate lifting size in the n candidate lifting sizes as the target lifting size.

With reference to the fourth aspect, in some implementations of the fourth aspect, that the second device determines a target lifting size based on a length of an information bit corresponding to the encoded data, an information column quantity of an LDPC base graph, and n bases includes: The second device determines the target lifting size based on the length of the information bit corresponding to the encoded data, the information column quantity of the LDPC base graph, the n bases, and a lifting size threshold.

With reference to the fourth aspect, in some implementations of the fourth aspect, that the second device determines the target lifting size based on the length of the information bit corresponding to the encoded data, the information column quantity of the LDPC base graph, the n bases, and a lifting size threshold includes: The second device determines, based on the length of the information bit corresponding to the encoded data, the information column quantity of the LDPC base graph, and the n bases, n candidate lifting sizes corresponding to the n bases, where lengths of information bits of LDPC codes corresponding to the n candidate lifting sizes are greater than or equal to the length of the information bit corresponding to the to-be-transmitted data; and if a smallest candidate lifting size in the n candidate lifting sizes is less than or equal to the lifting size threshold, the second device determines the smallest candidate lifting size as the target lifting size; or if the smallest candidate lifting size in the n candidate lifting sizes is greater than the lifting size threshold, the second device determines the lifting size threshold as the target lifting size.

With reference to the fourth aspect, in some implementations of the fourth aspect, a difference between different Uᵢ corresponding to the n shifting value sets is less than or equal to a third preset threshold.

With reference to the fourth aspect, in some implementations of the fourth aspect, the method further includes: The second device receives indication information from the first device, where the indication information indicates the target lifting size and/or the first shifting value set.

According to a fifth aspect, a data transmission method is provided. The method may be performed by a chip or a chip system on a terminal device side or a network device side. The method includes: A first device determines a plurality of bases based on a length of an information bit corresponding to to-be-transmitted data, an information column quantity of an LDPC base graph, and a plurality of first coefficients, where the plurality of bases are used to determine a plurality of lifting sizes, the plurality of lifting sizes are in one-to-one correspondence with the plurality of bases and the plurality of first coefficients, a first lifting size in the plurality of lifting sizes is equal to a product of a first basis corresponding to the first lifting size and the first coefficient corresponding to the first lifting size, the first base is in the plurality of bases, and the plurality of bases and the plurality of first coefficients are positive integers; the first device determines a target lifting size from the plurality of lifting sizes based on a threshold of a quantity of shortened bits; and the first device sends the to-be-transmitted data to a second device based on the target lifting size and a shifting value set corresponding to the target lifting size.

Based on the foregoing technical solution, the first device and the second device determine the plurality of bases based on the length of the information bit corresponding to the to-be-transmitted data, the information column quantity of the LDPC base graph, and the plurality of first coefficients, where the plurality of bases are in one-to-one correspondence with the plurality of lifting sizes; and then determine the target lifting size from the plurality of lifting sizes based on the stored threshold of the quantity of shortened bits, so that a difference between a code length of an LDPC code corresponding to the target lifting size and the length of the information bit corresponding to the to-be-transmitted data can be reduced as much as possible, and a quantity of shortened bits can be reduced, thereby improving decoding performance of a receive end.

With reference to the fifth aspect, in some implementations of the fifth aspect, the determining a target lifting size from the plurality of lifting sizes based on a threshold of a quantity of shortened bits includes: If a difference between a code length of an LDPC code corresponding to at least one of the plurality of lifting sizes and the length of the information bit is less than or equal to the threshold of the quantity of shortened bits, the first device determines the target lifting size from the at least one lifting size, where a value of the first coefficient corresponding to the target lifting size is the largest; or if a difference between a code length of an LDPC code corresponding to each of the plurality of lifting sizes and the length of the information bit is greater than the threshold of the quantity of shortened bits, the first device determines, as the target lifting size, a lifting size in the plurality of lifting sizes that corresponds to an LDPC code whose code length has a minimum difference from the length of the information bit.

With reference to the fifth aspect, in some implementations of the fifth aspect, a set of the plurality of first coefficients belongs to {2, 4, 8, 16, . . . , 2^{N}}, where N is an integer greater than 1.

With reference to the fifth aspect, in some implementations of the fifth aspect, the method further includes: The first device sends indication information to the second device, where the indication information indicates the target lifting size and/or the shifting value set corresponding to the target lifting size.

According to a sixth aspect, a data transmission method is provided. The method may be performed by a chip or a chip system on a terminal device side or a network device side. The method includes: A second device receives encoded data from a first device; the second device determines a plurality of bases based on a length of an information bit corresponding to the encoded data, an information column quantity of an LDPC base graph, and a plurality of first coefficients, where the plurality of bases are used to determine a plurality of lifting sizes, the plurality of lifting sizes are in one-to-one correspondence with the plurality of bases and the plurality of first coefficients, a first lifting size in the plurality of lifting sizes is equal to a product of a first basis corresponding to the first lifting size and the first coefficient corresponding to first lifting size, the first base is in the plurality of bases, and the plurality of bases and the plurality of first coefficients are positive integers; the second device determines a target lifting size from the plurality of lifting sizes based on a threshold of a quantity of shortened bits; and the second device decodes the encoded data based on the target lifting size and a shifting value set corresponding to the target lifting size.

The method provided in the sixth aspect is a receive end method corresponding to the fifth aspect. For beneficial effects thereof, directly refer to those of the fifth aspect.

With reference to the sixth aspect, in some implementations of the sixth aspect, the determining a target lifting size from the plurality of lifting sizes based on a threshold of a quantity of shortened bits includes: If a difference between a code length of an LDPC code corresponding to at least one of the plurality of lifting sizes and the length of the information bit is less than or equal to the threshold of the quantity of shortened bits, the second device determines the target lifting size from the at least one lifting size, where a value of the first coefficient corresponding to the target lifting size is the largest; or if a difference between a code length of an LDPC code corresponding to each of the plurality of lifting sizes and the length of the information bit is greater than the threshold of the quantity of shortened bits, the second device determines, as the target lifting size, a lifting size in the plurality of lifting sizes that corresponds to an LDPC code whose code length has a minimum difference from the length of the information bit.

With reference to the sixth aspect, in some implementations of the sixth aspect, a set of the plurality of first coefficients belongs to {2, 4, 8, 16, . . . , 2^{N}}, where N is an integer greater than 1.

With reference to the sixth aspect, in some implementations of the sixth aspect, the method further includes: The second device receives indication information from the first device, where the indication information indicates the target lifting size and/or the shifting value set corresponding to the target lifting size.

According to a seventh aspect, a communication apparatus is provided, and the apparatus may be used in the first device according to the first aspect. The apparatus includes: a processing unit, configured to determine a target lifting size based on a length of an information bit corresponding to to-be-transmitted data and an information column quantity of a low-density parity-check code LDPC base graph, where the target lifting size is in at least one of m lifting size sets, one lifting size set includes a lifting size corresponding to at least one of n bases, the m lifting size sets include lifting sizes corresponding to the n bases, a lifting size corresponding to an i^{th} base aᵢ in the n bases is determined based on a product of aᵢ and an integer power of 2, n is greater than m, and aᵢ is a positive integer, where the processing unit is further configured to determine a first shifting value set corresponding to the target lifting size, where the first shifting value set is in m shifting value sets; and a transceiver unit, configured to send the to-be-transmitted data based on the target lifting size and the first shifting value set.

With reference to the seventh aspect, in some implementations of the seventh aspect, the m shifting value sets are in one-to-one correspondence with the m lifting size sets.

With reference to the seventh aspect, in some implementations of the seventh aspect, a j^{th} shifting value set in the m shifting value sets belongs to {tⱼ,1+tⱼ,2+tⱼ, . . . , H₍ⱼ₎+tⱼ−1}, H₍ⱼ₎ is less than a maximum value of lifting sizes in a j^{th} lifting size set corresponding to the j^{th} shifting value set, tⱼ is an integer, and H₍ⱼ₎ is a positive integer.

With reference to the seventh aspect, in some implementations of the seventh aspect, a difference between different H₍ⱼ₎ corresponding to the m shifting value sets is less than or equal to a first preset threshold.

With reference to the seventh aspect, in some implementations of the seventh aspect, the transceiver unit is further configured to send indication information, where the indication information indicates the target lifting size and/or the first shifting value set.

According to an eighth aspect, a communication apparatus is provided, and the apparatus may be used in the second device according to the second aspect. The apparatus includes: a transceiver unit, configured to receive encoded data; and a processing unit, configured to determine a target lifting size based on a length of an information bit corresponding to the encoded data and an information column quantity of an LDPC base graph, where the target lifting size is in at least one of m lifting size sets, one lifting size set includes a lifting size corresponding to at least one of n bases, the m lifting size sets include lifting sizes corresponding to the n bases, a lifting size corresponding to an i^{th} base aᵢ in the n bases is determined based on a product of aᵢ and an integer power of 2, n is greater than m, and aᵢ is a positive integer, where the processing unit is further configured to determine a first shifting value set corresponding to the target lifting size, where the first shifting value set is in m shifting value sets; and the processing unit is further configured to decode the encoded data based on the target lifting size and the first shifting value set.

With reference to the eighth aspect, in some implementations of the eighth aspect, the m shifting value sets are in one-to-one correspondence with the m lifting size sets.

With reference to the eighth aspect, in some implementations of the eighth aspect, a j^{th} shifting value set in the m shifting value sets belongs to {tⱼ,1+tⱼ,2+tⱼ, . . . , H₍ⱼ₎+tⱼ−1}, H₍ⱼ₎ is less than a maximum value of lifting sizes in a j^{th} lifting size set corresponding to the j^{th} shifting value set, tⱼ is an integer, and H₍ⱼ₎ is a positive integer.

With reference to the eighth aspect, in some implementations of the eighth aspect, a difference between different H₍ⱼ₎ corresponding to the m shifting value sets is less than or equal to a first preset threshold.

With reference to the eighth aspect, in some implementations of the eighth aspect, the transceiver unit is further configured to receive indication information, where the indication information indicates the target lifting size and/or the first shifting value set.

According to a ninth aspect, a communication apparatus is provided, and the apparatus may be used in the first device according to the third aspect. The apparatus includes: a processing unit, configured to determine a target lifting size based on a length of an information bit corresponding to to-be-transmitted data, an information column quantity of an LDPC base graph, and n bases, where the target lifting size is in a plurality of lifting sizes corresponding to the n bases, a lifting size corresponding to an i^{th} base aᵢ in the n bases is aᵢ×2^{k}^{ᵢ}, aᵢ is a positive integer, and kᵢ is an integer greater than or equal to zero, where the processing unit is further configured to determine a first shifting value set corresponding to the target lifting size, where the first shifting value set is in n shifting value sets, the n shifting value sets are in one-to-one correspondence with the n bases, an i^{th} shifting value set in the n shifting value sets belongs to {tᵢ, 1+tᵢ, 2+tᵢ, . . . , Uᵢ+tᵢ−1}, Uᵢ is less than or equal to a second preset threshold, tᵢ is an integer, and Uᵢ is a positive integer; and a transceiver unit, configured to send the to-be-transmitted data based on the target lifting size and the first shifting value set.

With reference to the ninth aspect, in some implementations of the ninth aspect, the processing unit is specifically configured to: determine, based on the length of the information bit corresponding to the to-be-transmitted data, the information column quantity of the LDPC base graph, and the n bases, n candidate lifting sizes corresponding to the n bases, where lengths of information bits of LDPC codes corresponding to the n candidate lifting sizes are greater than or equal to the length of the information bit corresponding to the to-be-transmitted data; and determine a smallest candidate lifting size in the n candidate lifting sizes as the target lifting size.

With reference to the ninth aspect, in some implementations of the ninth aspect, the processing unit is specifically configured to determine the target lifting size based on the length of the information bit corresponding to the to-be-transmitted data, the information column quantity of the LDPC base graph, the n bases, and a lifting size threshold.

With reference to the ninth aspect, in some implementations of the ninth aspect, the processing unit is specifically configured to: determine, based on the length of the information bit corresponding to the to-be-transmitted data, the information column quantity of the LDPC base graph, and the n bases, n candidate lifting sizes corresponding to the n bases, where lengths of information bits of LDPC codes corresponding to the n candidate lifting sizes are greater than or equal to the length of the information bit corresponding to the to-be-transmitted data; and if a smallest candidate lifting size in the n candidate lifting sizes is less than or equal to the lifting size threshold, determine the smallest candidate lifting size as the target lifting size; or if the smallest candidate lifting size in the n candidate lifting sizes is greater than the lifting size threshold, determine the lifting size threshold as the target lifting size.

With reference to the ninth aspect, in some implementations of the ninth aspect, a difference between different Uᵢ corresponding to the n shifting value sets is less than or equal to a third preset threshold.

With reference to the ninth aspect, in some implementations of the ninth aspect, the transceiver unit is further configured to send indication information, where the indication information indicates the target lifting size and/or the first shifting value set.

According to a tenth aspect, a communication apparatus is provided, and the apparatus may be used in the second device according to the fourth aspect. The apparatus includes: a transceiver unit, configured to receive encoded data; and a processing unit, configured to determine a target lifting size based on a length of an information bit corresponding to the encoded data, an information column quantity of an LDPC base graph, and n bases, where the target lifting size is in a plurality of lifting sizes corresponding to the n bases, a lifting size corresponding to an i^{th} base aᵢ in the n bases is aᵢ×2^{k}^{ᵢ}, aᵢ is a positive integer, and kᵢ is an integer greater than or equal to zero, where the processing unit is further configured to determine a first shifting value set corresponding to the target lifting size, where the first shifting value set is in n shifting value sets, the n shifting value sets are in one-to-one correspondence with the n bases, an i^{th} shifting value set in the n shifting value sets belongs to {tᵢ, 1+tᵢ, 2+tᵢ, . . . , Uᵢ+tᵢ−1}, Uᵢ is less than or equal to a second preset threshold, tᵢ is an integer, and Uᵢ is a positive integer; and the processing unit is further configured to decode the encoded data based on the target lifting size and the first shifting value set.

With reference to the tenth aspect, in some implementations of the tenth aspect, the processing unit is specifically configured to: determine, based on the length of the information bit corresponding to the encoded data, the information column quantity of the LDPC base graph, and the n bases, n candidate lifting sizes corresponding to the n bases, where lengths of information bits of LDPC codes corresponding to the n candidate lifting sizes are greater than or equal to the length of the information bit corresponding to the to-be-transmitted data; and determine a smallest candidate lifting size in the n candidate lifting sizes as the target lifting size.

With reference to the tenth aspect, in some implementations of the tenth aspect, the processing unit is specifically configured to determine the target lifting size based on the length of the information bit corresponding to the encoded data, the information column quantity of the LDPC base graph, the n bases, and a lifting size threshold.

With reference to the tenth aspect, in some implementations of the tenth aspect, the processing unit is specifically configured to: determine, based on the length of the information bit corresponding to the encoded data, the information column quantity of the LDPC base graph, and the n bases, n candidate lifting sizes corresponding to the n bases, where lengths of information bits of LDPC codes corresponding to the n candidate lifting sizes are greater than or equal to the length of the information bit corresponding to the to-be-transmitted data; and if a smallest candidate lifting size in the n candidate lifting sizes is less than or equal to the lifting size threshold, determine the smallest candidate lifting size as the target lifting size; or if the smallest candidate lifting size in the n candidate lifting sizes is greater than the lifting size threshold, determine the lifting size threshold as the target lifting size.

With reference to the tenth aspect, in some implementations of the tenth aspect, a difference between different Uᵢ corresponding to the n shifting value sets is less than or equal to a third preset threshold.

With reference to the tenth aspect, in some implementations of the tenth aspect, the transceiver unit is further configured to receive indication information, where the indication information indicates the target lifting size and/or the first shifting value set.

According to an eleventh aspect, a communication apparatus is provided, and the apparatus may be used in the first device according to the fifth aspect. The apparatus includes: a processing unit, configured to determine a plurality of bases based on a length of an information bit corresponding to to-be-transmitted data, an information column quantity of an LDPC base graph, and a plurality of first coefficients, where the plurality of bases are used to determine a plurality of lifting sizes, the plurality of lifting sizes are in one-to-one correspondence with the plurality of bases and the plurality of first coefficients, a first lifting size in the plurality of lifting sizes is equal to a product of a first basis corresponding to the first lifting size and the first coefficient corresponding to the first lifting size, the first base is in the plurality of bases, and the plurality of bases and the plurality of first coefficients are positive integers, where the processing unit is further configured to determine a target lifting size from the plurality of lifting sizes based on a threshold of a quantity of shortened bits; and a transceiver unit, configured to send the to-be-transmitted data based on the target lifting size and a shifting value set corresponding to the target lifting size.

With reference to the eleventh aspect, in some implementations of the eleventh aspect, the processing unit is specifically configured to: if a difference between a code length of an LDPC code corresponding to at least one of the plurality of lifting sizes and the length of the information bit is less than or equal to the threshold of the quantity of shortened bits, determine the target lifting size from the at least one lifting size, where a value of the first coefficient corresponding to the target lifting size is the largest; or if a difference between a code length of an LDPC code corresponding to each of the plurality of lifting sizes and the length of the information bit is greater than the threshold of the quantity of shortened bits, determine, as the target lifting size, a lifting size in the plurality of lifting sizes that corresponds to an LDPC code whose code length has a minimum difference from the length of the information bit.

With reference to the eleventh aspect, in some implementations of the eleventh aspect, a set of the plurality of first coefficients belongs to {2, 4, 8, 16, . . . , 2^{N}}, where N is an integer greater than 1.

With reference to the eleventh aspect, in some implementations of the eleventh aspect, the transceiver unit is further configured to send indication information, where the indication information indicates the target lifting size and/or the shifting value set corresponding to the target lifting size.

According to a twelfth aspect, a communication apparatus is provided, and the apparatus may be used in the second device according to the sixth aspect. The apparatus includes: a transceiver unit, configured to receive encoded data; and a processing unit, configured to determine a plurality of bases based on a length of an information bit corresponding to the encoded data, an information column quantity of an LDPC base graph, and a plurality of first coefficients, where the plurality of bases are used to determine a plurality of lifting sizes, the plurality of lifting sizes are in one-to-one correspondence with the plurality of bases and the plurality of first coefficients, a first lifting size in the plurality of lifting sizes is equal to a product of a first basis corresponding to the first lifting size and the first coefficient corresponding to the first lifting size, the first base is in the plurality of bases, and the plurality of bases and the plurality of first coefficients are positive integers, where the processing unit is further configured to determine a target lifting size from the plurality of lifting sizes based on a threshold of a quantity of shortened bits; and the processing unit is further configured to decode the encoded data based on the target lifting size and a shifting value set corresponding to the target lifting size.

With reference to the twelfth aspect, in some implementations of the twelfth aspect, the processing unit is specifically configured to: if a difference between a code length of an LDPC code corresponding to at least one of the plurality of lifting sizes and the length of the information bit is less than or equal to the threshold of the quantity of shortened bits, determine the target lifting size from the at least one lifting size, where a value of the first coefficient corresponding to the target lifting size is the largest; or if a difference between a code length of an LDPC code corresponding to each of the plurality of lifting sizes and the length of the information bit is greater than the threshold of the quantity of shortened bits, determine, as the target lifting size, a lifting size in the plurality of lifting sizes that corresponds to an LDPC code whose code length has a minimum difference from the length of the information bit.

With reference to the twelfth aspect, in some implementations of the twelfth aspect, a set of the plurality of first coefficients belongs to {2, 4, 8, 16, . . . , 2′}, where N is an integer greater than 1.

With reference to the twelfth aspect, in some implementations of the twelfth aspect, the transceiver unit is further configured to receive indication information, where the indication information indicates the target lifting size and/or the shifting value set corresponding to the target lifting size.

According to a thirteenth aspect, a communication device is provided, including a processor and a memory. The memory is configured to store a computer program, and the processor is configured to execute the computer program stored in the memory, so that the method according to any one of the foregoing aspects or any one of the possible implementations of any aspect is performed.

According to a fourteenth aspect, a communication device is provided, including an input/output interface and a logic circuit. The input/output interface is configured to obtain input information and/or output information. The logic circuit is configured to perform the method according to any one of the foregoing aspects or any one of the possible implementations of any aspect, to perform processing and/or generate the output information based on the input information.

According to a fifteenth aspect, a communication system is provided, including the communication apparatus according to the seventh aspect, the ninth aspect, or the eleventh aspect, and the communication apparatus according to the eighth aspect, the tenth aspect, or the twelfth aspect.

According to a sixteenth aspect, a computer-readable storage medium is provided. The computer-readable medium stores a computer program, and when the computer program runs on a computer, the computer is enabled to perform the method according to any one of the foregoing aspects or any one of the possible implementations of any aspect.

According to a seventeenth aspect, a computer program product including instructions is provided. When the instructions are executed by a computer, a communication apparatus is enabled to implement the method according to any one of the foregoing aspects or any one of the possible implementations of any aspect.

The solutions provided in the seventh aspect to the seventeenth aspect are used to implement or cooperatively implement the methods provided in the first aspect to the sixth aspect, and therefore can achieve beneficial effects the same as or corresponding to those achieved by the first aspect to the sixth aspect. Details are not described herein again.

### BRIEF DESCRIPTION OF DRAWINGS

FIG. 1 is a diagram of a communication procedure of a communication system;

FIG. 2 is a diagram of a network architecture to which an embodiment of this application is applicable;

FIG. 3 is a schematic flowchart of a data transmission method according to an embodiment of this application;

FIG. 4 to FIG. 7 are diagrams of performance simulation in which all lifting sizes correspond to one shifting value set according to an embodiment of this application;

FIG. 8 is a diagram of performance simulation in which a value range of a shifting value set corresponding to a lifting size set is less than 192 according to an embodiment of this application;

FIG. 9 is a schematic flowchart of another data transmission method according to an embodiment of this application;

FIG. 10 is a diagram of performance simulation in which a shifting value set corresponding to a lifting size equal to 640 is used;

FIG. 11 is a diagram of performance simulation in which a shifting value set corresponding to a lifting size equal to 512 is used;

FIG. 12 is a schematic flowchart of another data transmission method according to an embodiment of this application;

FIG. 13 is a diagram of comparison between a quantity of shortened bits corresponding to a determined lifting size in an embodiment of this application and a quantity of shortened bits corresponding to a determined lifting size in 5G;

FIG. 14 to FIG. 19 are schematic block diagrams of a communication apparatus according to an embodiment of this application; and

FIG. 20 is a schematic block diagram of a communication device according to an embodiment of this application.

### DESCRIPTION OF EMBODIMENTS

The following describes the technical solutions in this application with reference to the accompanying drawings.

Embodiments of this application may be applied to various communication systems, for example, a wireless local area network (wireless local area network, WLAN) system, a narrowband-Internet of Things (narrowband-Internet of Things, NB-IoT) system, a global system for mobile communications (global system for mobile communications, GSM), an enhanced data rate for GSM evolution (enhanced data rate for GSM evolution, EDGE) system, a wideband code division multiple access (wideband code division multiple access, WCDMA) system, a code division multiple access 2000 (code division multiple access, CDMA 2000) system, a time division-synchronous code division multiple access (time division-synchronous code division multiple access, TD-SCDMA) system, a long term evolution (long term evolution, LTE) system, satellite communication, a sidelink (sidelink, SL), a fourth generation (fourth generation, 4G) system, a 5G system, or a new communication system emerging in the future. The communication system includes communication devices, and wireless communication may be performed between the communication devices by using an air interface resource. The communication devices may include a network device and a terminal device, and the network device may also be referred to as a base station device. The air interface resource may include at least one of a time domain resource, a frequency domain resource, a code resource, and a spatial resource.

The terminal device in embodiments of this application may include various handheld devices, vehicle-mounted devices, wearable devices, or computing devices that have a wireless communication function, or other processing devices connected to a wireless modem. The terminal may be a subscriber unit (subscriber unit), user equipment (user equipment, UE), a cellular phone (cellular phone), a smartphone (smartphone), a wireless data card, a personal digital assistant (personal digital assistant, PDA) computer, a tablet computer, a wireless modulator and demodulator (modulator and demodulator, modem), a laptop computer (laptop computer), a machine type communication (machine type communication, MTC) terminal, a wireless terminal in self driving (self driving), or the like. The user equipment includes vehicle user equipment. With emergence of an Internet of Things (Internet of Things, IoT) technology, more devices that previously do not have a communication function, for example, but not limited to, a household appliance, a transportation vehicle, a tool device, a service device, and a service facility, start to obtain a wireless communication function by being configured with a wireless communication unit, to access a wireless communication network to accept remote control. Such a device has the wireless communication function because the device is configured with the wireless communication unit, and therefore also belongs to a scope of wireless communication devices. In addition, the terminal device may also be referred to as a mobile station (mobile station, MS), a mobile device, a mobile terminal, a wireless terminal, a handheld device (handset), a client, a virtual reality (virtual reality, VR) terminal device, an augmented reality (augmented reality, AR) terminal device, a wireless terminal in industrial control, a wireless terminal in unmanned driving, a wireless terminal in remote medical, a wireless terminal in a smart grid, a wireless terminal in a smart city (smart city), a wireless terminal in a smart home (smart home), or the like. In embodiments of this application, an apparatus configured to implement a function of a terminal device may be a terminal device, or may be an apparatus, for example, a chip system, that can support the terminal device in implementing the function. The apparatus may be installed in the terminal device. In embodiments of this application, the chip system may include a chip, or may include a chip and another discrete component.

For example, the network device may be an access network device, an evolved NodeB (evolved NodeB, eNB), a radio network controller (radio network controller, RNC), a NodeB (NodeB, NB), a base station controller (base station controller, BSC), a base transceiver station (base transceiver station, BTS), a home evolved NodeB (home evolved NodeB, or home NodeB, HNB), a baseband unit (baseband unit, BBU), a device that bears a base station function in device to device (device to device, D2D), an access point (access point, AP) in a wireless fidelity (wireless fidelity, Wi-Fi) system, a radio relay node, a wireless backhaul node, a transmission point (transmission point, TP), a transmit/receive point (transmission and reception point, TRP), or the like; or may be a gNB or a transmission point (for example, a TRP or a TP) in new radio (new radio, NR), or one antenna panel or a group of antenna panels (including a plurality of antenna panels) of a base station in NR; or may be a network node that forms a gNB or a transmission point, for example, a baseband unit (building baseband unit, BBU) or a distributed unit (distributed unit, DU). Alternatively, the network device may be a vehicle-mounted device, a wearable device, a network device in a 6G network, a network device in a future evolved PLMN network, or a network device deployed on a satellite. This is not limited. In addition, based on a size of a provided service coverage area, the base station (base station, BS) may be further divided into a macro base station for providing a macro cell (macro cell), a micro base station for providing a micro cell (pico cell), a femto base station for providing a femto cell (femto cell), a relay station, an access point, and the like. With continuous evolution of a wireless communication technology, a future base station may also use another name.

The network device has abundant product forms. For example, in a product implementation process, a BBU and a radio frequency unit (radio frequency unit, RFU) may be integrated in a same device, and the device is connected to an antenna array by using a cable (for example, but not limited to a feeder). The BBU and the RFU may alternatively be disposed separately, are connected by using an optical fiber, and communicate with each other by using, for example but not limited to a common public radio interface (common public radio interface, CPRI) protocol. In this case, the RFU is usually referred to as a remote radio unit (remote radio unit, RRU), and is connected to the antenna array through a cable. In addition, the RRU may alternatively be integrated with the antenna array. For example, this structure is used for an active antenna unit (active antenna unit, AAU) product in a current market.

In addition, the BBU may be further decomposed into a plurality of parts. For example, the BBU may be further divided into a central unit (central unit, CU) and a distributed unit (distribute unit, DU) based on real-time performance of a processed service. The CU is responsible for processing non-real-time protocols and services, and the DU is responsible for processing physical-layer protocols and real-time services. Further, some physical layer functions may be separated from the BBU or the DU and integrated into the AAU.

Embodiments of this application may be implemented by using an application-specific integrated circuit (application-specific integrated circuit, ASIC) or a field programmable gate array (field programmable gate array, FPGA), or may be implemented by using program code in software/a memory. In a communication procedure of a communication system, embodiments of this application mainly relate to source coding, channel coding, channel decoding, and source recovery. FIG. 1 is a diagram of a communication procedure of a communication system.

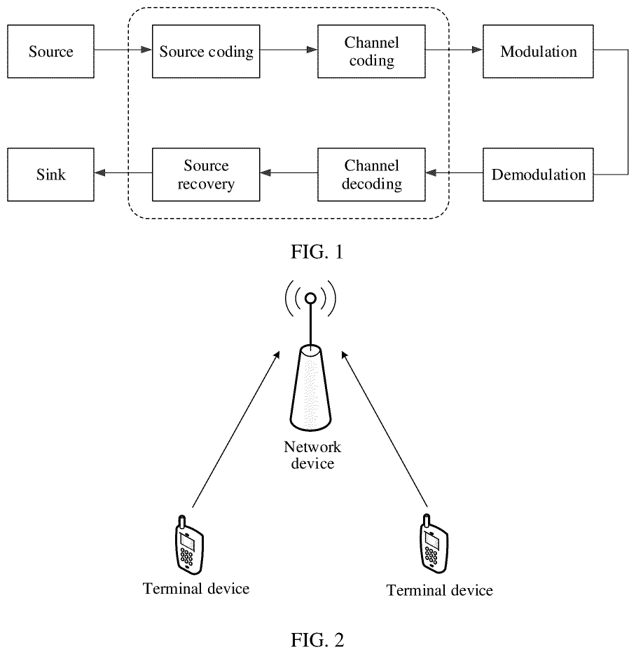

FIG. 2 is a diagram of a network architecture to which an embodiment of this application is applicable. The network architecture includes a network device and a terminal device. The network device may transmit data or control information to the terminal device, or the terminal device may transmit data or control information to the network device. The network device in this embodiment of this application may be a base station.

LDPC is a channel coding scheme that is very close to a Shannon limit, and has features of good performance, low complexity, and a flexible structure. An LDPC code is a research hotspot in the field of channel coding in recent years, and has been widely used in fields such as deep space communication, optical fiber communication, and satellite digital video and audio broadcasting. Currently, the LDPC code has been determined by 3GPP as a 5G data channel coding scheme.

The LDPC code is a type of linear code defined by using a check matrix. To make decoding feasible, the check matrix needs to meet “sparseness” when a code length is relatively long, that is, a density of is in the check matrix is relatively low. In other words, a quantity of 1s in the check matrix is required to be far less than a quantity of 0s. In addition, a longer code length indicates a lower density.

In manner of performing encoding by using the LDPC code, encoding is mainly performed by using a generator matrix. A mainstream LDPC code has a qusai-cyclic structure. A shifting value (shifting value, SV) of each block is set to avoid a bad structure such as a short loop, thereby increasing a code distance.

Currently, a decoding algorithm of the LDPC code mainly includes a minimum sum (min-sum, MS) algorithm and a belief propagation (belief propagation, BP) decoding algorithm. In terms of decoding performance, the BP decoding algorithm has better decoding performance, but the decoding algorithm has a large amount of information storage and a complex calculation manner, which is unfavorable to hardware implementation. Therefore, currently, an offset minimum sum (Offset-MS) decoding algorithm and a normalized minimum sum (Normalized-MS) decoding algorithm are used in an actual communication system.

In an actually used LDPC code, 1 in an LDPC base graph is extended into a cyclic shift matrix. A BG model BG of a QC-LDPC code=(X, Y, F), where X corresponds to a variable, Y corresponds to a check equation, and F corresponds to an edge relationship. After the BG is extended by using a lifting size Z_{c}, a Tanner graph is obtained. The Tanner graph is a bipartite graph G=(V, C, E), where V is a variable node, C is a check node, and E is an edge relationship. A quantity of columns of a check matrix corresponding to the BG is N=|V|=Z_{c}|X|, a quantity of rows of the check matrix corresponding to the BG is M=|C|=Z_{c}|Y|, and a quantity of non-zero elements in the check matrix corresponding to the BG is |E|=Z_{c}|F|, where Z_{c} is the lifting size.

A range of information bits supported by a 5G data channel is 1 to 8448. There are two check matrices described in the standard: a BG 1 and a BG 2. A same BG needs to use different lifting sizes to adapt to rate matching of different code lengths. Therefore, data receiving and transmitting ends need to store a lifting size table and a shifting value table.

A lifting size table corresponding to a 5G LDPC code is shown in Table 1. A lifting size in an i^{th} row in the lifting size table is aᵢ×2^{k}^{ᵢ}, where aᵢ∈{2,3,5,7,9,11,13,15} and max(kᵢ)∈{7,7,6,5,5,5,4,4}. In this embodiment of this application, aᵢ may be referred to as a basis of the lifting size. Each row of lifting sizes corresponds to one basis, and each row of lifting sizes may be referred to as a lifting size set. Row numbers in the lifting size table are in one-to-one correspondence with column numbers in a shifting value table, and each row of lifting sizes in the lifting size table corresponds to a group of shifting values. During rate matching, a lifting size is first determined, and then a shifting value corresponding to the lifting size is selected to construct a check matrix.

TABLE 1

| Set index i_{LS} | Lifting size set |
|---|---|
| 0 | {2, 4, 8, 16, 32, 64, 128, 256} |
| 1 | {3, 6, 12, 24, 48, 96, 192, 384} |
| 2 | {5, 10, 20, 40, 80, 160, 320} |
| 3 | {7, 14, 28, 56, 112, 224} |
| 4 | {9, 18, 36, 72, 144, 288} |
| 5 | {11, 22, 44, 88, 176, 352} |
| 6 | {13, 26, 52, 104, 208} |
| 7 | {15, 30, 60, 120, 240} |

Rows in the lifting size table are in one-to-one correspondence with columns in the shifting value table. A part of the shifting value table corresponding to the 5G LDPC code is shown in Table 2.

TABLE 2

| H_{BG} | | Shifting value V_{i, j} | | | | | | | |
|---|---|---|---|---|---|---|---|---|---|
| Row | Column | i_{LS} | | | | | | | |
| number i | number j | 0 | 1 | 2 | 3 | 4 | 5 | 6 | 7 |
| 0 | 0 | 250 | 307 | 73 | 223 | 211 | 294 | 0 | 135 |
| | 1 | 69 | 19 | 15 | 16 | 198 | 118 | 0 | 227 |
| | 2 | 226 | 50 | 103 | 94 | 188 | 167 | 0 | 126 |
| | 3 | 159 | 369 | 49 | 91 | 186 | 330 | 0 | 134 |
| | 5 | 100 | 181 | 240 | 74 | 219 | 207 | 0 | 84 |
| | 6 | 10 | 216 | 39 | 10 | 4 | 165 | 0 | 83 |
| | 9 | 59 | 317 | 15 | 0 | 29 | 243 | 0 | 53 |
| | 10 | 229 | 288 | 162 | 205 | 144 | 250 | 0 | 225 |
| | 11 | 110 | 109 | 215 | 216 | 116 | 1 | 0 | 205 |
| | 12 | 191 | 17 | 164 | 21 | 216 | 339 | 0 | 128 |
| | 13 | 9 | 357 | 133 | 215 | 115 | 201 | 0 | 75 |
| | 15 | 195 | 215 | 298 | 14 | 233 | 53 | 0 | 135 |
| | 16 | 23 | 106 | 110 | 70 | 144 | 347 | 0 | 217 |
| | 18 | 190 | 242 | 113 | 141 | 95 | 304 | 0 | 220 |
| | 19 | 35 | 180 | 16 | 198 | 216 | 167 | 0 | 90 |
| | 20 | 239 | 330 | 189 | 104 | 73 | 47 | 0 | 105 |
| | 21 | 31 | 346 | 32 | 81 | 261 | 188 | 0 | 137 |
| | 22 | 1 | 1 | 1 | 1 | 1 | 1 | 0 | 1 |
| | 23 | 0 | 0 | 0 | 0 | 0 | 0 | 0 | 0 |

In the 5G NR LDPC code, a plurality of lifting sizes share a same group of shifting values. The shifting values depend on random search and have no numerical features or structural features. To support fine-grained encoding and decoding performance, each base corresponds to a group of lifting sizes, and each group of lifting sizes corresponds to a group of shifting values. A transmit end and a receive end for data transmission need to store a plurality of groups of shifting values, resulting in a complex QSN. In addition, to support a maximum value aᵢ×2^{k}^{_{max(i), of the lifting size, a value range of a corresponding shifting value is}} 0 to aᵢ×2^{k}^{ₘₐₓ₍ᵢ₎}−1. Consequently, a quantity of shifting values that need to be stored is large, and a QSN is complex.

Therefore, embodiments of this application provide a data transmission method, to reduce a quantity of shifting values that need to be stored, thereby reducing complexity of a QSN.

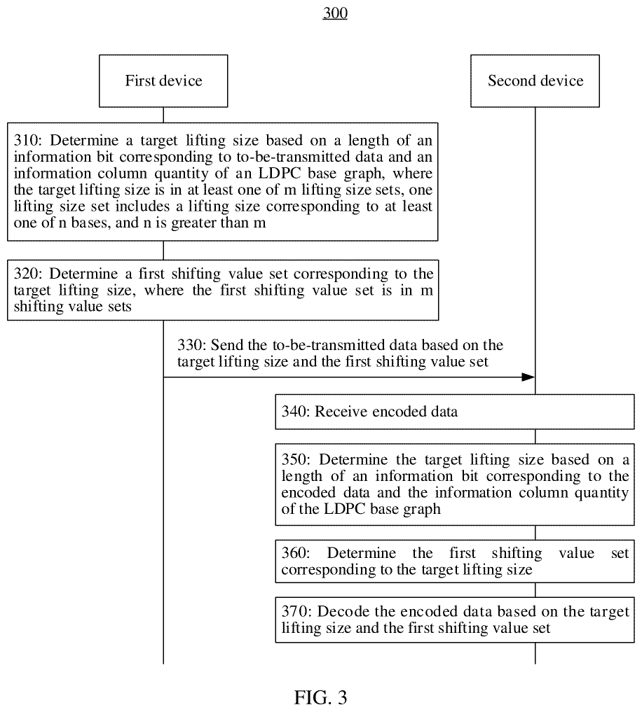

FIG. 3 is a schematic flowchart of a data transmission method 300 according to an embodiment of this application. In this embodiment of this application, a first device may be a terminal device or a network device, a second device may be a terminal device or a network device, and the network device may be a base station. The first device and the second device store m lifting size sets and m shifting value sets.

310: The first device determines a target lifting size based on a length of an information bit corresponding to to-be-transmitted data and an information column quantity of an LDPC base graph, where the target lifting size is in at least one of the m lifting size sets, one of the m lifting size sets includes a lifting size corresponding to at least one of n bases, the m lifting size sets include lifting sizes corresponding to the n bases, and a lifting size corresponding to an i^{th} base aᵢ in the n bases is determined based on a product of aᵢ and an integer power of 2. For example, a lifting size is aᵢ×2^{k}^{ᵢ}, where kₘᵢₙ₍ᵢ₎≤kᵢ≤kₘₐₓ₍ᵢ₎, kₘᵢₙ₍ᵢ₎ is greater than or equal to 0, n is greater than m, 0≤i←n−1, aᵢ is a positive integer, and kᵢ is an integer.

A product of the information column quantity of the LDPC base graph and the target lifting size is greater than or equal to the length of the information bit corresponding to the to-be-transmitted data. In this embodiment of this application, the length of the information bit may be understood as a quantity of information bits, the LDPC base graph includes an LDPC BG 1 or an LDPC BG 2 in 5G, and the LDPC base graph may alternatively be another base graph. This is not limited.

That one of the m lifting size sets includes a lifting size corresponding to at least one of n bases may be understood as that one of the m lifting size sets may include a lifting size corresponding to one or more of the n bases. Quantities of bases corresponding to lifting sizes included in different lifting size sets in the m lifting size sets may be the same or may be different, and bases corresponding to lifting sizes included in different lifting size sets in the m lifting size sets may overlap or may not overlap at all.

For example, quantities of bases corresponding to lifting sizes included in different lifting size sets in the m lifting size sets are the same, and bases corresponding to lifting sizes included in different lifting size sets do not overlap. Using m=4 and n=8 as an example, eight rows of lifting sizes in Table 1 may be combined into four rows of lifting sizes. Each of the combined four rows of lifting sizes may be referred to as a lifting size set. In the combined four rows of lifting sizes, quantities of bases corresponding to lifting sizes in different rows are the same, and each row of lifting sizes corresponds to two bases. The combined four rows of lifting sizes are shown in Table 3. Bases corresponding to lifting sizes in a first row include 2 and 3, bases corresponding to lifting sizes in a second row include 5 and 7, bases corresponding to lifting sizes in a third row include 9 and 11, and bases corresponding to lifting sizes in a fourth row include 13 and 15.

TABLE 3

| Row | |
|---|---|
| number | |
| Rⱼ | Lifting size set |
| 0 | {2, 4, 8, 16, 32, 64, 128, 256, 3, 6, 12, 24, 48, 96, 192, 384} |
| 1 | {5, 10, 20, 40, 80, 160, 320, 7, 14, 28, 56, 112, 224} |
| 2 | {9, 18, 36, 72, 144, 288, 11, 22, 44, 88, 176, 352} |
| 3 | {13, 26, 52, 104, 208, 15, 30, 60, 120, 240} |

For example, quantities of bases corresponding to lifting sizes included in different lifting size sets in the m lifting size sets are different, and bases corresponding to lifting sizes included in different lifting size sets do not overlap. Using m=4 and n=8 as an example, eight rows of lifting sizes in Table 1 may be combined into four rows of lifting sizes. Each of the combined four rows of lifting sizes may be referred to as a lifting size set. In the combined four rows of lifting sizes, quantities of bases corresponding to lifting sizes in different rows are different. The combined four rows of lifting sizes are shown in Table 4. Bases corresponding to lifting sizes in a first row include 2, bases corresponding to lifting sizes in a second row include 3 and 5, bases corresponding to lifting sizes in a third row include 7, 9, and 11, and bases corresponding to lifting sizes in a fourth row include 13 and 15.

TABLE 4

| Row | |
|---|---|
| number | |
| Rⱼ | Lifting size set |
| 0 | {2, 4, 8, 16, 32, 64, 128, 256} |
| 1 | {3, 6, 12, 24, 48, 96, 192, 384, 5, 10, 20, 40, 80, 160, 320} |
| 2 | {7, 14, 28, 56, 112, 224, 9, 18, 36, 72, 144, 288, 11, 22, 44, 88, |
| | 176, 352} |
| 3 | {13, 26, 52, 104, 208, 15, 30, 60, 120, 240} |

For example, quantities of bases corresponding to lifting sizes included in different lifting size sets in the m lifting size sets are different, and bases corresponding to lifting sizes included in different lifting size sets overlap. Using m=4 and n=8 as an example, eight rows of lifting sizes in Table 1 may be combined into four rows of lifting sizes. Each of the combined four rows of lifting sizes may be referred to as a lifting size set. In the combined four rows of lifting sizes, quantities of bases corresponding to lifting sizes in different rows are different, and bases corresponding to lifting sizes in different rows overlap. The combined four rows of lifting sizes are shown in Table 5. Bases corresponding to lifting sizes in a first row include 2 and 3, bases corresponding to lifting sizes in a second row include 3 and 5, bases corresponding to lifting sizes in a third row include 7, 9, and 11, and bases corresponding to lifting sizes in a fourth row include 13 and 15.

TABLE 5

| Row | |
|---|---|
| number | |
| Rⱼ | Lifting size set |
| 0 | {2, 4, 8, 16, 32, 64, 128, 256, 3, 6, 12, 24, 48, 96, 192, 384} |
| 1 | {3, 6, 12, 24, 48, 96, 192, 384, 5, 10, 20, 40, 80, 160, 320} |
| 2 | {7, 14, 28, 56, 112, 224, 9, 18, 36, 72, 144, 288, 11, 22, 44, 88, |
| | 176, 352} |
| 3 | {13, 26, 52, 104, 208, 15, 30, 60, 120, 240} |

Optionally, all the lifting sizes corresponding to the n bases are combined into one lifting size set, the lifting size corresponding to the i^{th} base aᵢ in the n bases is aᵢ×2^{k}^{ᵢ}, where 1≤kᵢ≤kₘₐₓ₍ᵢ₎. A minimum value of the lifting sizes included in the combined lifting size set is 2aᵢ. Compared with that a minimum value of lifting sizes included in a lifting size set is aᵢ, in this example, the minimum value of the lifting sizes included in the lifting size set is 2aᵢ. This can well avoid a short loop structure of a Tanner graph obtained after the LDPC base graph is extended by using the lifting size in the lifting size set.

Using m=1 and n=8 as an example, eight rows of lifting sizes in Table 1 may be combined into one row of lifting sizes. The combined one row of lifting sizes may be referred to as a lifting size set. Bases corresponding to lifting sizes included in the lifting size set include 2, 3, 5, 7, 9, 11, 13, and 15, but the lifting size set does not include 2, 3, 5, 7, 9, 11, 13, and 15.

The LDPC BG 1 in 5G is used as an example. An information column quantity of the LDPC BG 1 is 22, and a minimum value of lifting sizes included in a lifting size set is 2aᵢ. If a length K of an information bit corresponding to to-be-transmitted data is greater than 22×15=330, the lifting size included in the lifting size set may meet a transmission requirement. However, the standard specifies that a minimum information bit length supported by the LDPC BG1 is 293. Because a length range of an information bit that cannot be supported because the lifting size aᵢ is deleted is 293 to 330, and lifting sizes 14 and 15 need to be used in this range, an additional lifting size 15 may be added to the lifting size set. For example, the lifting size set may be represented as {aᵢ×2^{k}^{ᵢ}|aᵢ=2,3,5,7,9,11,13; 1≤kᵢ≤kₘₐₓ₍ᵢ₎}U{15×2^{k}^{₁₅}|0≤k₁₅≤kₘₐₓ₍₁₅₎}.

320: The first device determines a first shifting value set corresponding to the target lifting size, where the first shifting value set is in the m shifting value sets. Optionally, the m shifting value sets are in one-to-one correspondence with the m lifting size sets.

Specifically, after determining the target lifting size based on the length of the information bit corresponding to the to-be-transmitted data and the information column quantity of the LDPC base graph, the first device determines a target lifting size set to which the target lifting size belongs, where the target lifting size set is in the m lifting size sets. Then, the first device determines, from the m shifting value sets, the first shifting value set corresponding to the target lifting size set.

For example, when the target lifting size is in one of the m lifting size sets, the first device determines the target lifting size set to which the target lifting size belongs, and determines, from the m shifting value sets based on the one-to-one correspondence between the lifting size sets and the shifting value sets, the first shifting value set corresponding to the target lifting size set. When the target lifting size is in a plurality of lifting size sets in the m lifting size sets, the first device determines the plurality of lifting size sets to which the target lifting size belongs; determines, based on the length of the information bit corresponding to the to-be-transmitted data, one target lifting size set from the plurality of lifting size sets to which the target lifting size belongs; and determines, from the m shifting value sets based on the one-to-one correspondence between the lifting size sets and the shifting value sets, the first shifting value set corresponding to the target lifting size set.

330: The first device sends the to-be-transmitted data to the second device based on the target lifting size and the first shifting value set. Specifically, the first device determines, based on the target lifting size, the first shifting value set, and the LDPC base graph, an LDPC code matrix corresponding to the LDPC base graph, where the LDPC code matrix includes an LDPC code generator matrix or an LDPC code check matrix; the first device encodes the to-be-transmitted data based on the LDPC code matrix; and the first device sends, to the second device, to-be-transmitted data encoded by using the LDPC code matrix.

340: The second device receives encoded data from the first device, where the encoded data is to-be-transmitted data that is encoded by the first device by using the LDPC code matrix.

350: The second device determines a target lifting size based on a length of an information bit corresponding to the encoded data and the information column quantity of the LDPC base graph, where the target lifting size is in at least one of the m lifting size sets, one of the m lifting size sets includes a lifting size corresponding to at least one of the n bases, and the m lifting size sets include the lifting sizes corresponding to the n bases.

360: The second device determines the first shifting value set corresponding to the target lifting size.

Specifically, after determining the target lifting size based on the length of the information bit corresponding to the to-be-transmitted data and the information column quantity of the LDPC base graph, the second device determines a target lifting size set to which the target lifting size belongs, where the target lifting size set is in the m lifting size sets. Then, the second device determines, from the m shifting value sets, the first shifting value set corresponding to the target lifting size set.

For example, when the target lifting size is in one of the m lifting size sets, the second device determines the target lifting size set to which the target lifting size belongs, and determines, from the m shifting value sets based on the one-to-one correspondence between the lifting size sets and the shifting value sets, the first shifting value set corresponding to the target lifting size set. When the target lifting size is in a plurality of lifting size sets in the m lifting size sets, the second device determines the plurality of lifting size sets to which the target lifting size belongs; determines, based on the length of the information bit corresponding to the to-be-transmitted data, one target lifting size set from the plurality of lifting size sets to which the target lifting size belongs; and determines, from the m shifting value sets based on the one-to-one correspondence between the lifting size sets and the shifting value sets, the first shifting value set corresponding to the target lifting size set.

370: The second device decodes the encoded data based on the target lifting size and the first shifting value set.

In the technical solution provided in this embodiment of this application, one of the m lifting size sets stored in the first device and the second device includes a lifting size corresponding to one or more of the n bases, the m lifting size sets correspond to the m shifting value sets, and m is less than n. Compared with that n shifting value sets corresponding to the n bases are supported, in this embodiment of this application, a transmit end (the first device) and a receive end (the second device) for data transmission need to support only the m shifting value sets. Therefore, a quantity of shifting values that need to be stored can be reduced, and complexity of a QSN can be reduced.

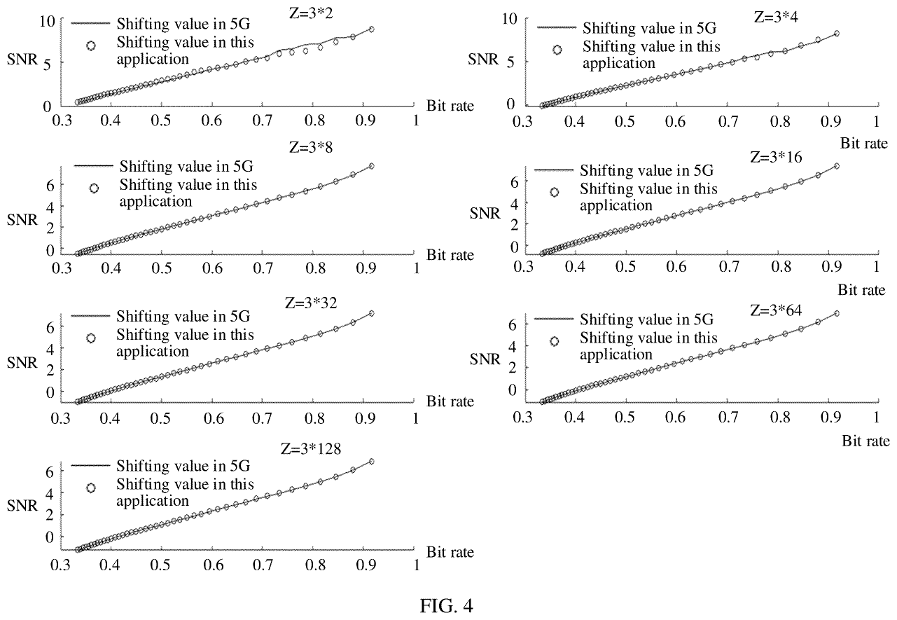

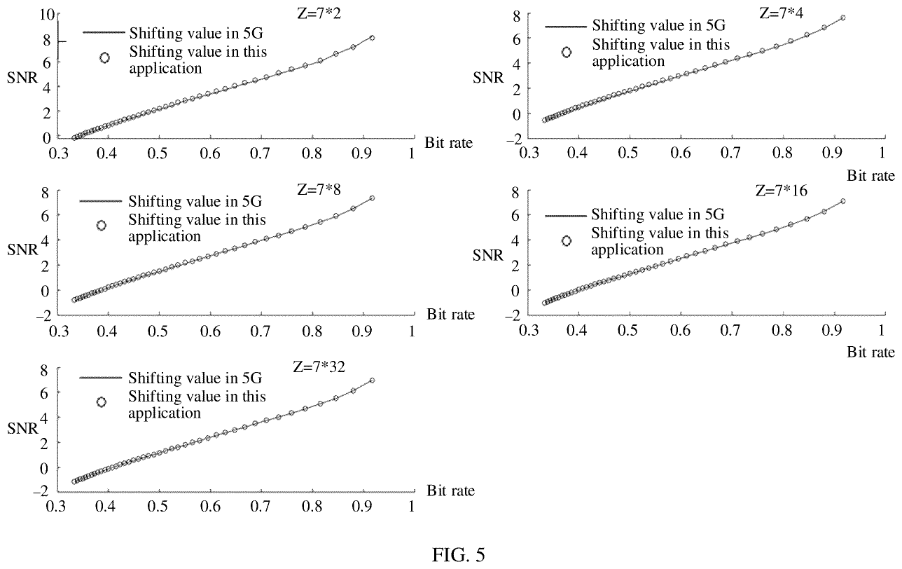

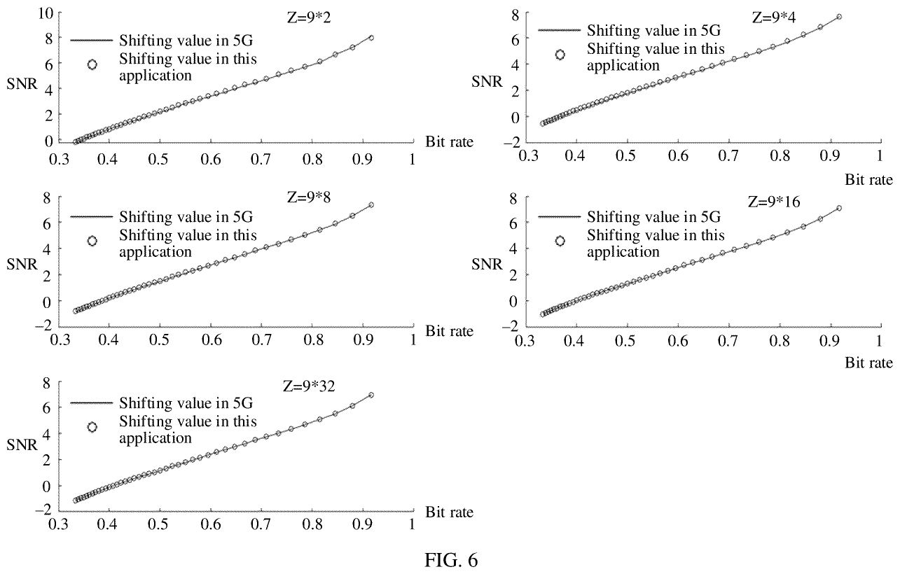

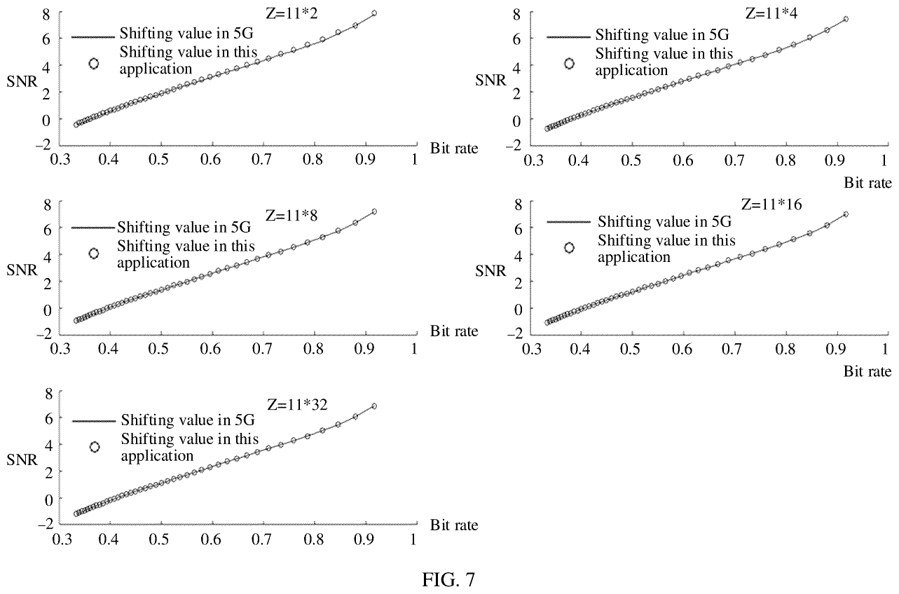

FIG. 4 to FIG. 7 are diagrams of performance simulation in which all lifting sizes correspond to one shifting value set according to an embodiment of this application. A horizontal coordinate is a bit rate, and a vertical coordinate is a signal-to-noise ratio (signal-to-noise ratio, SNR) when a block error rate (block error rate, BLER) is 1/100. A used base graph is an LDPC BG 1 in 5G. A basis corresponding to a lifting size in FIG. 4 is 3, a basis corresponding to a lifting size in FIG. 5 is 7, a basis corresponding to a lifting size in FIG. 6 is 9, and a basis corresponding to a lifting size in FIG. 7 is 11. It can be learned that, a block error rate corresponding to a shifting value determined in 5G is almost consistent with that corresponding to a shifting value determined in this embodiment of this application, and encoding and decoding performance is not affected.

Optionally, the first device sends indication information to the second device, where the indication information indicates the target lifting size and/or the first shifting value set. Correspondingly, the second device receives the indication information from the first device. When the first device indicates the target lifting size and the first shifting value set to the second device by using the indication information, after the second device receives the encoded data from the first device, the second device may directly decode the encoded data based on the target lifting size and the first shifting value set that are indicated by the indication information, and does not need to determine the target lifting size and the first shifting value set by using the second device.

Optionally, a j^{th} shifting value set in the m shifting value sets belongs to {tⱼ,1+tⱼ,2+tⱼ, . . . , H₍ⱼ₎+tⱼ−1}, H₍ⱼ₎ is less than a maximum value of lifting sizes in a j^{th} lifting size set corresponding to the j^{th} shifting value set, tⱼ is an integer, H₍ⱼ₎ is a positive integer, and 0≤j≤m−1. tⱼ is any integer set based on hardware implementation, and a value of tⱼ may also be 0. Values of tⱼ corresponding to different shifting value sets in the m shifting value sets may be the same or may be different.

Because H₍ⱼ₎ is less than the maximum value Zₘₐₓ₍ⱼ₎ of the lifting sizes in the j^{th} lifting size set corresponding to the j^{th} shifting value set, where Zₘₐₓ₍ⱼ₎=aⱼ×2^{k}^{_{max (j)}}) value range of a shifting value set that needs to be supported by the first device and the second device is less than a value range of [0, 1, 2, . . . , aⱼ×2^{k}^{ₘₐₓ₍ⱼ₎}−1]. Therefore, a quantity of shifting values that need to be stored can be further reduced, and complexity of a QSN can be further reduced.

For example, H₍ⱼ₎ is determined based on the maximum value of the lifting sizes in the j^{th} lifting size set corresponding to the j^{th} shifting value set, where

$${H}_{( j )} = \frac{{Z}_{max ( j )}}{{h}_{j}} ,$$

1<hⱼ≤Zₘₐₓ₍ⱼ₎, and hⱼ is a positive integer. Because values of maximum values of lifting sizes in different lifting size sets may be different, specific values of hⱼ corresponding to different shifting value sets may be different. For example, there may be no numerical relationship between H₍ⱼ₎ and Zₘₐₓ₍ⱼ₎, and H₍ⱼ₎ is only used to indicate a value range of a shifting value.

Optionally, a difference between different H₍ⱼ₎ corresponding to the m shifting value sets is less than or equal to a first preset threshold. For example, the first preset threshold may be a minimum value in different H₍ⱼ₎. Values of H₍ⱼ₎ corresponding to different shifting value sets are relatively consistent, so that complexity of QSN hardware corresponding to the different shifting value sets is relatively consistent.

FIG. 8 is a diagram of performance simulation in which a value range of a shifting value set corresponding to a lifting size set is less than 192 according to an embodiment of this application. A horizontal coordinate is a code rate, a vertical coordinate is an SNR when a BLER is 1/100, a basis corresponding to a lifting size is 3, and a used base graph is an LDPC BG 1 in 5G. It can be learned that, a block error rate corresponding to a shifting value determined in 5G is almost consistent with that corresponding to a shifting value determined in this embodiment of this application, and encoding and decoding performance is not affected.

An embodiment of this application provides another data transmission method. In the method, neither a first device nor a second device needs to store a lifting size set, and only needs to store n bases. A lifting size corresponding to an i^{th} base aᵢ in the n bases is aᵢ×2^{k}^{ᵢ}, where kᵢ may be any integer, and there is no limitation on a threshold of kᵢ. In the method, data of more information bits can be transmitted.

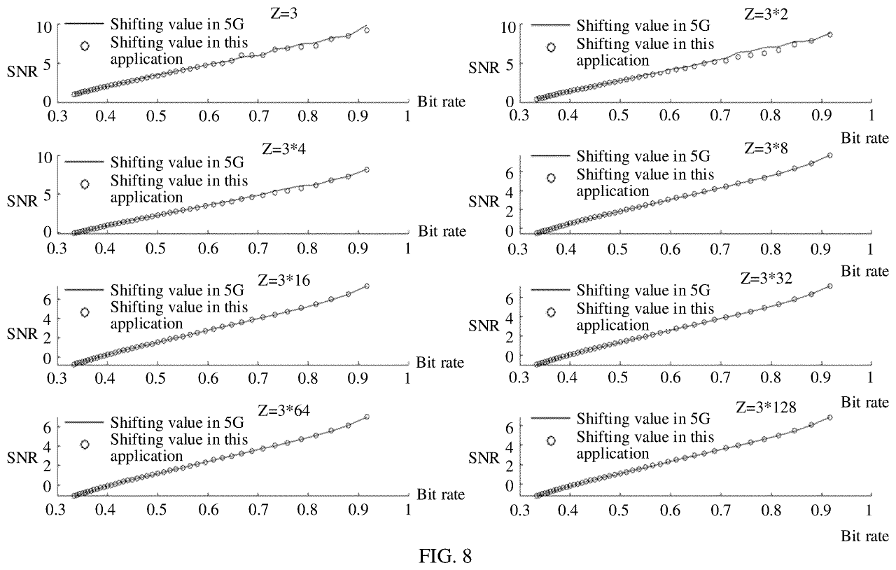

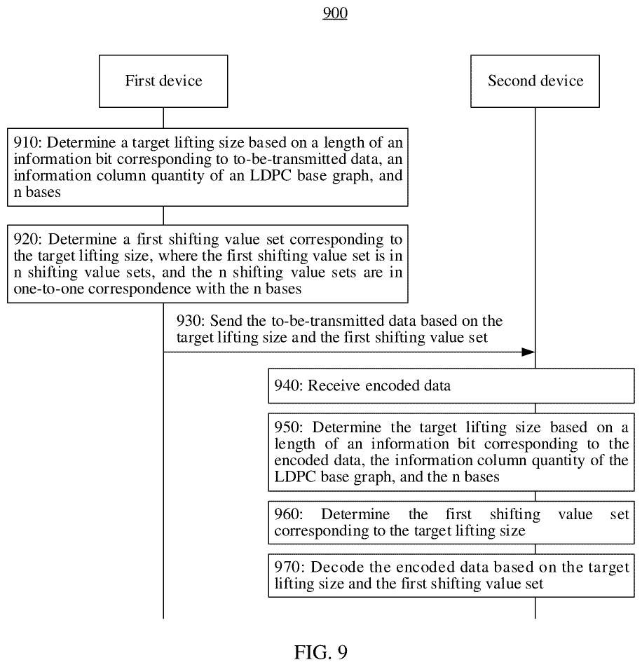

FIG. 9 is a schematic flowchart of another data transmission method 900 according to an embodiment of this application. In this embodiment of this application, a first device may be a terminal device or a network device, a second device may be a terminal device or a network device, and the network device may be a base station.

910: The first device determines a target lifting size based on a length of an information bit of to-be-transmitted data, an information column quantity of an LDPC base graph, and n bases, where the target lifting size is in a plurality of lifting sizes corresponding to the n bases, a lifting size corresponding to an i^{th} base aᵢ in the n bases is aᵢ×2^{k}^{ᵢ}, 0≤i≤n−1, aᵢ is a positive integer, and kᵢ is an integer greater than or equal to zero.

For example, the first device determines, based on the length of the information bit corresponding to the to-be-transmitted data, the information column quantity of the LDPC base graph, and the n bases, n candidate lifting sizes corresponding to the n bases. That lengths of information bits of LDPC codes corresponding to the n candidate lifting sizes are greater than or equal to the length of the information bit of the to-be-transmitted data may be understood as that a product of the information column quantity of the LDPC base graph and the candidate lifting size is greater than or equal to the length of the information bit corresponding to the to-be-transmitted data. The first device determines a smallest candidate lifting size in the n candidate lifting sizes as the target lifting size.

The smallest candidate lifting size in the n candidate lifting sizes is determined as the target lifting size, so that a quantity of shortened bits (shorten bits) can be reduced, and decoding performance of a receive end (the second device) can be improved. The quantity of shortened bits is a difference between a length of an information bit of an LDPC code corresponding to the target lifting size and the length of the information bit corresponding to to-be-transmitted data. A smaller quantity of shortened bits indicates fewer changes to the LDPC base graph, and decoding performance of the receive end is more stable.

The length of the information bit corresponding to the to-be-transmitted data may be represented by K, the information column quantity of the LDPC base graph may be represented by K₀, and the target lifting size may be represented by Z. First, for each of the n bases, a minimum

$${k}_{i}^{0}$$

that meets K₀×aᵢ×2^{k}^{ᵢ}≥K is determined. Then, the n candidate lifting sizes corresponding to the n bases are determined based on the minimum

$${k}_{i}^{0}$$

corresponding to each basis, where a candidate lifting size corresponding to the basis aᵢ may be represented as

$${a}_{i} \times {2}^{{k}_{i}^{0}} .$$

Finally the smallest candidate lifting size in the n candidate lifting sizes is determined as the target lifting size, where the target lifting size is

$$Z = min {a}_{i} \times {2}^{{k}_{i}^{0}} .$$

For example, aᵢ∈{2,3,5,7,9,11,13,15}, K=440, and K₀=22. A minimum

$${k}_{0}^{0}$$

corresponding to a basis a₀=2 is equal to 4, and a candidate lifting size corresponding to the basis a₀ is 32; a minimum

$${k}_{1}^{0}$$

corresponding to a basis aᵢ=3 is equal to 3, and a candidate lifting size corresponding to the basis a₁ is 24; a minimum

$${k}_{2}^{0}$$

corresponding to a basis a₂=5 is equal to 2, and a candidate lifting size corresponding to the basis a₂ is 20; a minimum

$${k}_{3}^{0}$$

corresponding to a basis a₃=7 is equal to 2, and a candidate lifting size corresponding to the basis a₃ is 28; and a minimum

$${k}_{4}^{0}$$

corresponding to a basis a₄=9 is equal to 2, and a candidate lifting size corresponding to the basis a₄ is 36; a minimum

$${k}_{5}^{0}$$

corresponding to a basis a₅=11 is equal to 1, and a candidate lifting size corresponding to the basis a₅ is 22; a minimum

$${k}_{6}^{0}$$

corresponding to a basis a₆=13 is equal to 1, and a candidate lifting size corresponding to the basis a₆ is 26; and a minimum

$${k}_{7}^{0}$$

corresponding to a basis a₇=15 is equal to 1, and a candidate lifting size corresponding to the basis a₇ is 30. Eight candidate lifting sizes corresponding to eight bases are respectively 32, 24, 20, 28, 36, 22, 26, and 30, and a minimum value of the eight candidate lifting sizes is 20. Therefore, the target lifting size determined by the first device is 20.

Optionally, the first device determines the target lifting size based on the length of the information bit corresponding to the to-be-transmitted data, the information column quantity of the LDPC base graph, the n bases, and a lifting size threshold. The lifting size threshold may be predefined or specified in a protocol. The lifting size threshold is stored in the first device and the second device. This is not specifically limited in this embodiment of this application.

For example, the first device determines, based on the length of the information bit corresponding to the to-be-transmitted data, the information column quantity of the LDPC base graph, and the n bases, n candidate lifting sizes corresponding to the n bases, where a length of an information bit of an LDPC code corresponding to each of the n candidate lifting sizes is greater than or equal to the length of the information bit of the to-be-transmitted data. If a smallest candidate lifting size in the n candidate lifting sizes is less than or equal to the lifting size threshold, the first device determines the smallest candidate lifting size as the target lifting size; or if the smallest candidate lifting size in the n candidate lifting sizes is greater than the lifting size threshold, the first device determines the lifting size threshold as the target lifting size.

The length of the information bit corresponding to the to-be-transmitted data may be represented by K, the information column quantity of the LDPC base graph may be represented by K₀, the lifting size threshold may be represented by Zₘₐₓ, and the target lifting size may be represented by Z. First, for each of the n bases, a minimum

$${k}_{i}^{0}$$

that meets K₀×aᵢ×2^{k}^{ᵢ}≥K is determined. Then, the n candidate lifting sizes corresponding to the n bases are determined based on the minimum

$${k}_{i}^{0}$$

corresponding to each basis where a candidate lifting size corresponding to the basis aᵢ may be represented as

$${a}_{i} \times {2}^{{k}_{i}^{0}} .$$

Finally, the target lifting size is determined based on the n candidate lifting sizes and the lifting size threshold. If the smallest candidate lifting size min

$${a}_{i} \times {2}^{{k}_{i}^{0}}$$

in the n candidate lifting sizes is less than or equal to Zₘₐₓ, the target lifting size is Z=min

$${a}_{i} \times {2}^{{k}_{i}^{0}} ;$$

or if the smallest candidate lifting size min

$${a}_{i} \times {2}^{{k}_{i}^{0}}$$

in then candidate lifting sizes is greater than Zₘₐₓ, the target lifting size Z=Zₘₐₓ.

For example, aᵢ∈{2,3,5,7,9,11,13,15}, K=8800, K₀=22, and Zₘₐₓ=500. A minimum

$${k}_{0}^{0}$$

corresponding to a basis a₀=2 is equal to 8, and a candidate lifting size corresponding to the basis a₀ is 512; a minimum

$${k}_{1}^{0}$$

corresponding to a basis a₁=3 is equal to 8, and a candidate lifting size corresponding to the basis a₁ is 768; a minimum

$${k}_{2}^{0}$$

corresponding to a basis a₂=5 is equal to 7, and a candidate lifting size corresponding to the basis a₂ is 640; a minimum

$${k}_{3}^{0}$$

corresponding to a basis a₃=7 is equal to 6, and a candidate lifting size corresponding to the basis
a₃ is 448; and a minimum

$${k}_{4}^{0}$$

corresponding to a basis a₄=9 is equal to 6, and a candidate lifting size corresponding to the basis a₄ is 576; a minimum

$${k}_{5}^{0}$$

corresponding to a basis a₅=11 is equal to 6, and a candidate lifting size corresponding to the basis a₅ is 704; a minimum

$${k}_{6}^{0}$$

corresponding to a basis a₆=13 is equal to 5, and a candidate lifting size corresponding to the basis a₆ is 416; and a minimum

$${k}_{7}^{0}$$

corresponding to a basis a₇=15 is equal to 5, and a candidate lifting size corresponding to the basis a₇ is 480. Eight candidate lifting sizes corresponding to eight bases are respectively 512, 768, 640, 448, 576, 704, 416, 480, and a minimum value of the eight candidate lifting sizes is 416. Because 416 is less than Zₘₐₓ, it is determined that the target lifting size is 416.

920: The first device determines a first shifting value set corresponding to the target lifting size, where the first shifting value set is in n shifting value sets, the n shifting value sets are in one-to-one correspondence with the n bases, an i^{th} shifting value set in the n shifting value sets belongs to {tᵢ,1+tᵢ,2+tᵢ, . . . , Uᵢ+tᵢ−1}, Uᵢ is less than or equal to a second preset threshold, tᵢ is an integer, and Uᵢ is a positive integer. For example, the second preset threshold may be determined based on a minimum value and a maximum value in Uᵢ.

Optionally, a difference between different Uᵢ corresponding to the n shifting value sets is less than or equal to a third preset threshold. The third preset threshold may be determined based on different application scenarios and the length of the information bit corresponding to the to-be-transmitted data. Values of Uᵢ corresponding to different shifting value sets are relatively consistent, so that complexity of QSN hardware corresponding to the different shifting value sets is relatively consistent.

930: The first device sends the to-be-transmitted data based on the target lifting size and the first shifting value set. Specifically, the first device determines, based on the target lifting size, the first shifting value set, and the LDPC base graph, an LDPC code matrix corresponding to the LDPC base graph, where the LDPC code matrix includes an LDPC code generator matrix or an LDPC code check matrix; the first device encodes the to-be-transmitted data based on the LDPC code matrix; and the first device sends, to the second device, to-be-transmitted data encoded by using the LDPC code matrix.

940: The second device receives encoded data from the first device, where the encoded data is to-be-transmitted data that is encoded by the first device by using the LDPC code matrix.

950: The second device determines the target lifting size based on a length of an information bit corresponding to the encoded data, the information column quantity of the LDPC base graph, and the n bases.

For example, the second device determines, based on the length of the information bit corresponding to the encoded data, the information column quantity of the LDPC base graph, and the n bases, n candidate lifting sizes corresponding to the n bases, where a length of an information bit of an LDPC code corresponding to each of the n candidate lifting sizes is greater than or equal to the length of the information bit corresponding to the to-be-transmitted data; and the second device determines a smallest candidate lifting size in the n candidate lifting sizes as the target lifting size.

Optionally, the second device determines the target lifting size based on the length of the information bit corresponding to the encoded data, the information column quantity of the LDPC base graph, the n bases, and a lifting size threshold.

For example, the second device determines, based on the length of the information bit corresponding to the encoded data, the information column quantity of the LDPC base graph, and the n bases, n candidate lifting sizes corresponding to the n bases, where a length of an information bit of an LDPC code corresponding to each of the n candidate lifting sizes is greater than or equal to the length of the information bit corresponding to the to-be-transmitted data. If a smallest candidate lifting size in the n candidate lifting sizes is less than or equal to the lifting size threshold, the second device determines the smallest candidate lifting size as the target lifting size; or if the smallest candidate lifting size in the n candidate lifting sizes is greater than the lifting size threshold, the second device determines the lifting size threshold as the target lifting size.

It should be understood that specific implementations in which the first device and the second device determine the target lifting size are consistent.

960: The second device determines the first shifting value set corresponding to the target lifting size.

970: The second device decodes the encoded data based on the target lifting size and the first shifting value set.

In the technical solution provided in this embodiment of this application, because there is no limitation on a threshold of kᵢ corresponding to a basis, there is no maximum value or threshold for a lifting size corresponding to the basis. When the length of the information bit corresponding to the to-be-transmitted data is relatively large, the determined target lifting size is also relatively large, so that data of more information bits can be transmitted. In addition, when the length of the information bit corresponding to the to-be-transmitted data increases to a specific extent, a value of a shifting value in the first shifting value set corresponding to the target lifting size does not increase, and a value range of the shifting value in the first shifting value set does not increase. Therefore, when a code length of an LDPC code increases to a specific extent, complexity of a QSN no longer increases with an increase in the code length of the LDPC code, and an area gain of an encoding chip or a decoding chip gradually increases with an increase in the code length of the LDPC code.

Optionally, the first device sends indication information to the second device, where the indication information indicates the target lifting size and/or the first shifting value set. Correspondingly, the second device receives the indication information from the first device. When the first device indicates the target lifting size and the first shifting value set to the second device by using the indication information, after the second device receives the encoded data from the first device, the second device may directly decode the encoded data based on the target lifting size and the first shifting value set that are indicated by the indication information, and does not need to determine the target lifting size and the first shifting value set by using the second device.

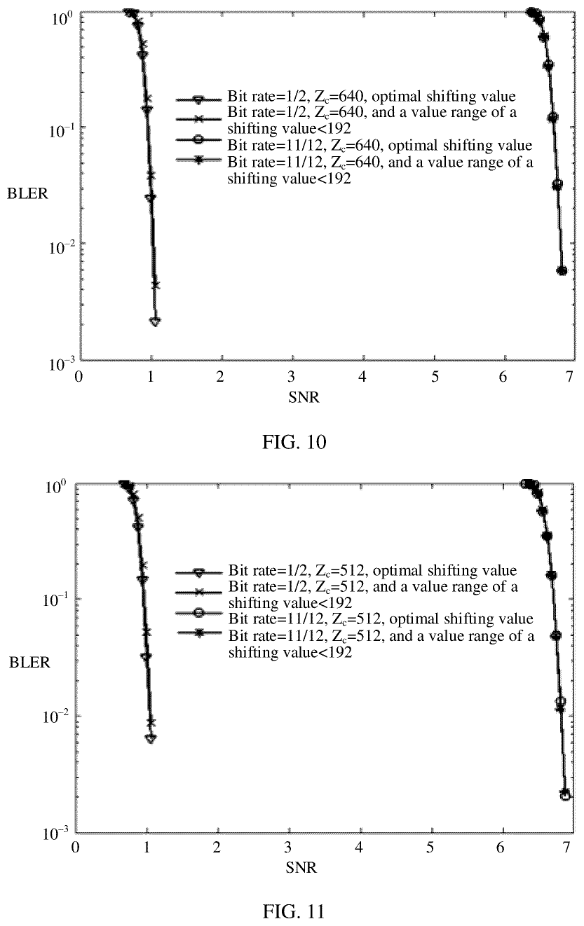

FIG. 10 is a diagram of performance simulation in which a shifting value set corresponding to a lifting size equal to 640 is used. A basis corresponding to the lifting size 640 is 2. FIG. 11 is a diagram of performance simulation in which a shifting value set corresponding to a lifting size equal to 512 is used. A basis corresponding to the lifting size 512 is 5. A horizontal coordinate is an SNR, and a vertical coordinate is a BLER. In one case, a shifting value corresponding to a lifting size is determined from a shifting value set {0, 1, 2, . . . , 191}, and a value range of the shifting value is less than 192. In another case, a shifting value corresponding to a lifting size is determined in a manner of selecting an optimal shifting value corresponding to an LDPC code in 5G. It can be learned that, regardless of whether a shifting value is determined from a shifting value set with a limited value range, or a shifting value is determined in the manner of selecting the optimal shifting value corresponding to the LDPC code in 5G, block error rates are almost consistent, and encoding and decoding performance is not affected.

An embodiment of this application provides another data transmission method, to reduce a quantity of shortened bits, thereby improving decoding performance of a receive end.

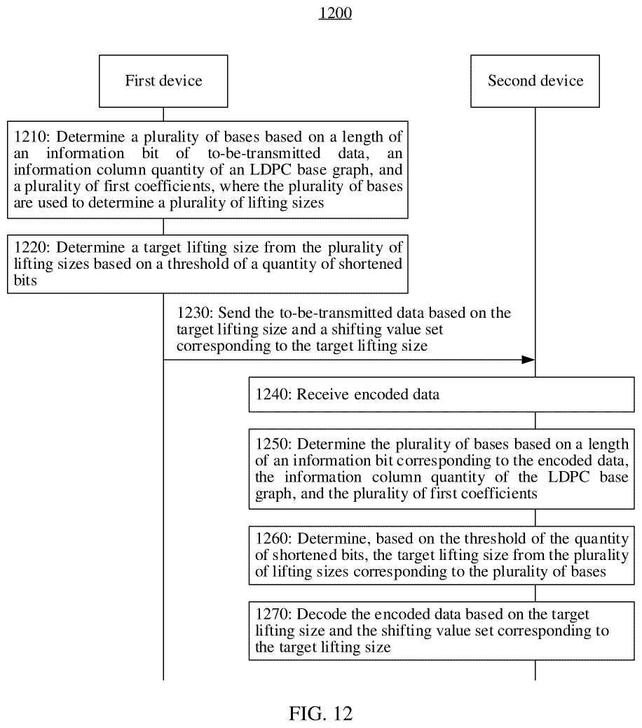

FIG. 12 is a schematic flowchart of another data transmission method 1200 according to an embodiment of this application. In this embodiment of this application, a first device may be a terminal device or a network device, a second device may be a terminal device or a network device, and the network device may be a base station. The first device and the second device store a plurality of first coefficients used to determine a lifting size and a threshold of a quantity of shortened bits, and do not need to store a lifting size set, and a determined lifting size is no longer a multiple of a fixed basis.

1210: The first device determines a plurality of bases based on a length of an information bit corresponding to to-be-transmitted data, an information column quantity of an LDPC base graph, and the plurality of first coefficients, where the plurality of bases are used to determine a plurality of lifting sizes, the plurality of lifting sizes are in one-to-one correspondence with the plurality of bases and the plurality of first coefficients, each first coefficient corresponds to one basis, a first lifting size in the plurality of lifting sizes is equal to a product of a first basis corresponding to the first lifting size and the first coefficient corresponding to the first lifting size, the first base is in the plurality of bases, and the plurality of bases and the plurality of first coefficients are positive integers.

A product of the information column quantity of the LDPC base graph and any one of the plurality of lifting sizes is greater than or equal to the length of the information bit corresponding to the to-be-transmitted data. In this embodiment of this application, the length of the information bit may be understood as a quantity of information bits, and the LDPC base graph includes an LDPC BG 1 or an LDPC BG 2 in 5G.

Optionally, the plurality of first coefficients are a power set of 2, and a set of the plurality of first coefficients belongs to {2, 4, 8, 16, . . . , 2^{N}}, where N is an integer greater than 1. For example, N=8, and the set of the plurality of first coefficients belongs to {2, 4, 8, 16, 32, 64, 128, 256}.

1220: The first device determines a target lifting size from the determined plurality of lifting sizes based on a threshold of a quantity of shortened bits. The threshold of the quantity of shortened bits may be a function of a length of an information bit, and the function is known to the first device and the second device. The threshold of the quantity of shortened bits may alternatively be a value specified in a protocol or a predefined value.

For example, the threshold of the quantity of shortened bits is related to a length range of an information bit, and different length ranges of the information bit correspond to different thresholds of the quantity of shortened bits. For example, the length range of the information bit includes N1-N2 and N3-N4, a threshold that is of the quantity of shortened bits and that corresponds to N1-N2 may be N2/K, and a threshold that is of the quantity of shortened bits and that corresponds to N3-N4 may be N4/K, where K is a fixed value.

Optionally, if a difference between a code length of an LDPC code corresponding to at least one of the plurality of lifting sizes and the length of the information bit is less than or equal to the threshold of the quantity of shortened bits, the first device determines the target lifting size from the at least one lifting size, where a value of the first coefficient corresponding to the target lifting size is the largest. This may be understood as follows: If a difference between a code length of an LDPC code corresponding to one or more lifting sizes in the plurality of lifting sizes and the length of the information bit is less than or equal to the threshold of the quantity of shortened bits, the first device determines the target lifting size from the one or more lifting sizes that are less than or equal to the threshold of the quantity of shortened bits.

Optionally, if a difference between a code length of an LDPC code corresponding to each of the plurality of lifting sizes and the length of the information bit is greater than the threshold of the quantity of shortened bits, the first device determines, as the target lifting size, a lifting size in the plurality of lifting sizes that corresponds to an LDPC code whose code length has a minimum difference from the length of the information bit. This may be understood as follows: If there is no lifting size in the plurality of lifting sizes that corresponds to an LDPC code whose code length has a difference less than or equal to the threshold of the quantity of shortened bits from the length of the information bit, the first device determines, as the target lifting size, the lifting size in the plurality of lifting sizes that corresponds to an LDPC code whose code length has the minimum difference from the length of the information bit.

For example, the length of the information bit corresponding to the to-be-transmitted data may be represented by K, the information column quantity of the LDPC base graph may be represented by K₀, the plurality of first coefficients may be represented by I, a quantity of the plurality of first coefficients may be represented by J, and the threshold of the quantity of shortened bits may be represented by d. First, a minimum aⱼ that meets K₀×aⱼ×Iⱼ≥K is calculated, where

$${a}_{j} = ⌈ \frac{K}{{K}_{0} \times {I}_{j}} ⌉ ,$$

┌ ┐ represents rounding up, and 0≤j≤J. Then, a plurality of lifting sizes aⱼ×Iⱼ corresponding to a plurality of aⱼ are determined, and a difference dⱼ=K₀×aⱼ×Iⱼ−K between a code length of an LDPC code corresponding to each of the plurality lifting sizes and the length of the information bit corresponding to the to-be-transmitted data is determined. Finally, the target lifting size is determined based on dⱼ and d. When dⱼ≤d exists, a lifting size corresponding to a maximum Iⱼ that meets the condition is selected as the target lifting size. When dⱼ≤d does not exist, a lifting size corresponding to a minimum dⱼ is selected as the target lifting size.

For example, I={2, 4, 8, 16, 32, 64, 128, 256}, J=8, K=440, K₀=22, and d=1. I₀=2 corresponds to a basis a₀=10, a candidate lifting size corresponding to the basis a₀ is 20, and d₀=0; I₁=4 corresponds to a basis a₁=5, a candidate lifting size corresponding to the basis a₁ is 20, and d₁=0; I₂=8 corresponds to a basis a₂=3, a candidate lifting size corresponding to the basis a₂ is 24, and d₂=88; I₃=16 corresponds to a basis a₃=2, a candidate lifting size corresponding to the basis a₃ is 32, and d₃=264; I₄=32 corresponds to a basis a₄=1, a candidate lifting size corresponding to the basis a₄ is 32, and d₄=264; I₅=64 corresponds to a basis a₅=1, a candidate lifting size corresponding to the basis a₅ is 64, and d₅=968; I₆=128 corresponds to a basis a₆=1, a candidate lifting size corresponding to the basis a₆ is 128, and d₆=2376; and I₇=256 corresponds to a basis a₇=1, a candidate lifting size corresponding to the basis a₇ is 256, and d₇=5192. Because dⱼ≤d exists, the selected target lifting size is the lifting size 20 corresponding to I₁=4.

The first device determines a shifting value set corresponding to the target lifting size. Optionally, all Iⱼ corresponds to a same shifting value set. Optionally, different Iⱼ corresponds to different shifting value sets. That I={2, 4, 8, 16, 32, 64, 128, 256} and J=8 are used as an example. For example, I₀-I₃ corresponds to a first shifting value set, and I₄-I₇ corresponds to a second shifting value set.

1230: The first device sends the to-be-transmitted data to the second device based on the target lifting size and the shifting value set corresponding to the target lifting size. Specifically, the first device determines, based on the target lifting size, the shifting value set corresponding to the target lifting size, and the LDPC base graph, an LDPC code matrix corresponding to the LDPC base graph, where the LDPC code matrix includes an LDPC code generator matrix or an LDPC code check matrix; the first device encodes the to-be-transmitted data based on the LDPC code matrix; and the first device sends, to the second device, to-be-transmitted data encoded by using the LDPC code matrix.

1240: The second device receives encoded data from the first device, where the encoded data is to-be-transmitted data that is encoded by the first device by using the LDPC code matrix.

1250: The second device determines the plurality of bases based on a length of an information bit corresponding to the encoded data, the information column quantity of the LDPC base graph, and the plurality of first coefficients, where the plurality of bases are used to determine a plurality of lifting sizes, the plurality of lifting sizes are in one-to-one correspondence with the plurality of bases and the plurality of first coefficients, a first lifting size in the plurality of lifting sizes is equal to a product of a first basis corresponding to the first lifting size and the first coefficient corresponding to the first lifting size, the first base is in the plurality of bases, and the plurality of bases and the plurality of first coefficients are positive integers.

1260: The second device determines the target lifting size from the plurality of lifting sizes based on a threshold of a quantity of shortened bits.

Optionally, if a difference between a code length of an LDPC code corresponding to at least one of the plurality of lifting sizes and the length of the information bit is less than or equal to the threshold of the quantity of shortened bits, the second device determines the target lifting size from the at least one lifting size, where a value of the first coefficient corresponding to the target lifting size is the largest. This may be understood as follows: If a difference between a code length of an LDPC code corresponding to one or more lifting sizes in the plurality of lifting sizes and the length of the information bit is less than or equal to the threshold of the quantity of shortened bits, the second device determines the target lifting size from the one or more lifting sizes that are less than or equal to the threshold of the quantity of shortened bits.

Optionally, if a difference between a code length of an LDPC code corresponding to each of the plurality of lifting sizes and the length of the information bit is greater than the threshold of the quantity of shortened bits, the second device determines, as the target lifting size, a lifting size in the plurality of lifting sizes that corresponds to an LDPC code whose code length has a minimum difference from the length of the information bit. This may be understood as follows: If there is no lifting size in the plurality of lifting sizes that corresponds to an LDPC code whose code length has a difference less than or equal to the threshold of the quantity of shortened bits from the length of the information bit, the second device determines, as the target lifting size, the lifting size in the plurality of lifting sizes that corresponds to an LDPC code whose code length has the minimum difference from the length of the information bit.

1270: The second device determines the shifting value set corresponding to the target lifting size, and decodes the encoded data based on the target lifting size and the shifting value set corresponding to the target lifting size.

Optionally, the first device sends indication information to the second device, where the indication information indicates the target lifting size and/or the shifting value set corresponding to the target lifting size. Correspondingly, the second device receives the indication information from the first device. When the first device indicates, to the second device by using the indication information, the target lifting size and the shifting value set corresponding to the target lifting size, after the second device receives the encoded data from the first device, the second device may directly decode the encoded data based on the target lifting size and the shifting value set that are indicated by the indication information, and does not need to determine, by using the second device, the target lifting size and the shifting value set corresponding to the target lifting size.

In the technical solution provided in this embodiment of this application, the first device and the second device determine the plurality of bases based on the length of the information bit corresponding to the to-be-transmitted data, the information column quantity of the LDPC base graph, and the plurality of first coefficients, where the plurality of bases are in one-to-one correspondence with the plurality of lifting sizes; and then determine the target lifting size from the plurality of lifting sizes based on the stored threshold of the quantity of shortened bits, so that a difference between a code length of an LDPC code corresponding to the target lifting size and the length of the information bit corresponding to the to-be-transmitted data can be reduced as much as possible, and a quantity of shortened bits can be reduced, thereby improving decoding performance of a receive end.

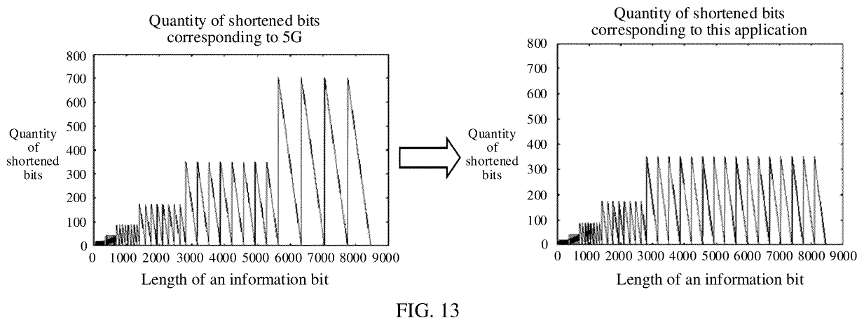

FIG. 13 is a diagram of comparison between a quantity of shortened bits corresponding to a determined lifting size in an embodiment of this application and a quantity of shortened bits corresponding to a determined lifting size in 5G. It can be learned that, in the technical solution in this embodiment of this application, a quantity of shortened bits can be reduced, thereby improving decoding performance of a receive end.

The foregoing describes the data transmission method provided in embodiments of this application. The following describes entities for performing the foregoing data transmission method.

FIG. 14 is a schematic block diagram of a communication apparatus 1400 according to an embodiment of this application. The apparatus may be used in the first device in the method embodiment in FIG. 3. The communication apparatus 1400 includes:
a processing unit 1410, configured to determine a target lifting size based on a length of an information bit corresponding to to-be-transmitted data and an information column quantity of a low-density parity-check code LDPC base graph, where the target lifting size is in at least one of m lifting size sets, one lifting size set includes a lifting size corresponding to at least one of n bases, the m lifting size sets include lifting sizes corresponding to the n bases, a lifting size corresponding to an i^{th} base a; in the n bases is determined based on a product of aᵢ and an integer power of 2, n is greater than m, and aᵢ is a positive integer, where
the processing unit 1410 is further configured to determine a first shifting value set corresponding to the target lifting size, where the first shifting value set is in m shifting value sets; and
a transceiver unit 1420, configured to send the to-be-transmitted data based on the target lifting size and the first shifting value set.

Optionally, the m shifting value sets are in one-to-one correspondence with the m lifting size sets.

Optionally, a j^{th} shifting value set in the m shifting value sets belongs to {tⱼ,1+tⱼ,2+tⱼ, . . . , H₍ⱼ₎+tⱼ−1}, H₍ⱼ₎ is less than a maximum value of lifting sizes in a j^{th} lifting size set corresponding to the j^{th} shifting value set, tⱼ is an integer, and H₍ⱼ₎ is a positive integer.

Optionally, a difference between different H₍ⱼ₎ corresponding to the m shifting value sets is less than or equal to a first preset threshold.

Optionally, the transceiver unit 1420 is further configured to send indication information, where the indication information indicates the target lifting size and/or the first shifting value set.

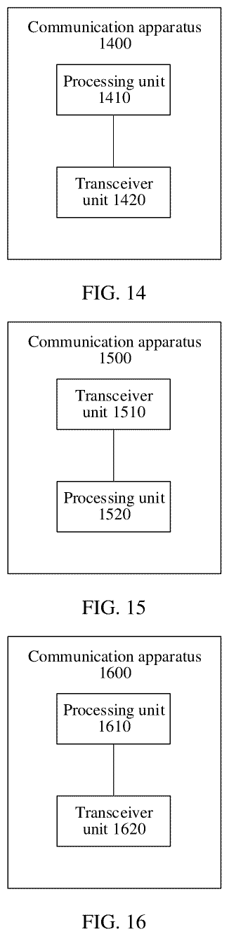

FIG. 15 is a schematic block diagram of another communication apparatus 1500 according to an embodiment of this application. The apparatus may be used in the second device in the method embodiment in FIG. 3. The communication apparatus 1500 includes:
a transceiver unit 1510, configured to receive encoded data; and
a processing unit 1520, configured to determine a target lifting size based on a length of an information bit corresponding to the encoded data and an information column quantity of an LDPC base graph, where the target lifting size is in at least one of m lifting size sets, one lifting size set includes a lifting size corresponding to at least one of n bases, the m lifting size sets include lifting sizes corresponding to the n bases, a lifting size corresponding to an i^{th} base aᵢ in the n bases is determined based on a product of aᵢ and an integer power of 2, n is greater than m, and aᵢ is a positive integer.

The processing unit 1520 is further configured to determine a first shifting value set corresponding to the target lifting size, where the first shifting value set is in m shifting value sets.

The processing unit 1520 is further configured to decode the encoded data based on the target lifting size and the first shifting value set.

Optionally, the m shifting value sets are in one-to-one correspondence with the m lifting size sets.

Optionally, a j^{th} shifting value set in the m shifting value sets belongs to {tⱼ,1+tⱼ,2+tⱼ, . . . , H₍ⱼ₎+tⱼ−1}, H₍ⱼ₎ is less than a maximum value of lifting sizes in a j^{th} lifting size set corresponding to the j^{th} shifting value set, tⱼ is an integer, and H₍ⱼ₎ is a positive integer.

Optionally, a difference between different H₍ⱼ₎ corresponding to the m shifting value sets is less than or equal to a first preset threshold.

Optionally, the transceiver unit 1510 is further configured to receive indication information, where the indication information indicates the target lifting size and/or the first shifting value set.

FIG. 16 is a schematic block diagram of another communication apparatus 1600 according to an embodiment of this application. The apparatus may be used in the first device in the method embodiment in FIG. 9. The communication apparatus 1600 includes:
a processing unit 1610, configured to determine a target lifting size based on a length of an information bit corresponding to to-be-transmitted data, an information column quantity of an LDPC base graph, and n bases, where the target lifting size is in a plurality of lifting sizes corresponding to the n bases, a lifting size corresponding to an i^{th} base aᵢ in the n bases is aᵢ×2^{k}^{ᵢ}, aᵢ is a positive integer, and kᵢ is an integer greater than or equal to zero, where
the processing unit 1610 is further configured to determine a first shifting value set corresponding to the target lifting size, where the first shifting value set is in n shifting value sets, the n shifting value sets are in one-to-one correspondence with the n bases, an i^{th} shifting value set in the n shifting value sets belongs to {tᵢ,1+tᵢ,2+tᵢ, . . . , Uᵢ+tᵢ−1}, Uᵢ is less than or equal to a second preset threshold, tᵢ is an integer, and Uᵢ is a positive integer; and
a transceiver unit 1620, configured to send the to-be-transmitted data based on the target lifting size and the first shifting value set.

Optionally, the processing unit 1610 is specifically configured to: determine, based on the length of the information bit corresponding to the to-be-transmitted data, the information column quantity of the LDPC base graph, and the n bases, n candidate lifting sizes corresponding to the n bases, where lengths of information bits of LDPC codes corresponding to the n candidate lifting sizes are greater than or equal to the length of the information bit corresponding to the to-be-transmitted data; and determine a smallest candidate lifting size in the n candidate lifting sizes as the target lifting size.

Optionally, the processing unit 1610 is specifically configured to determine the target lifting size based on the length of the information bit corresponding to the to-be-transmitted data, the information column quantity of the LDPC base graph, the n bases, and a lifting size threshold.

Optionally, the processing unit 1610 is specifically configured to: determine, based on the length of the information bit corresponding to the to-be-transmitted data, the information column quantity of the LDPC base graph, and the n bases, n candidate lifting sizes corresponding to the n bases, where lengths of information bits of LDPC codes corresponding to the n candidate lifting sizes are greater than or equal to the length of the information bit corresponding to the to-be-transmitted data; and if a smallest candidate lifting size in the n candidate lifting sizes is less than or equal to the lifting size threshold, determine the smallest candidate lifting size as the target lifting size; or if the smallest candidate lifting size in the n candidate lifting sizes is greater than the lifting size threshold, determine the lifting size threshold as the target lifting size.

Optionally, a difference between different Uᵢ corresponding to the n shifting value sets is less than or equal to a third preset threshold.

Optionally, the transceiver unit 1620 is further configured to send indication information, where the indication information indicates the target lifting size and/or the first shifting value set.

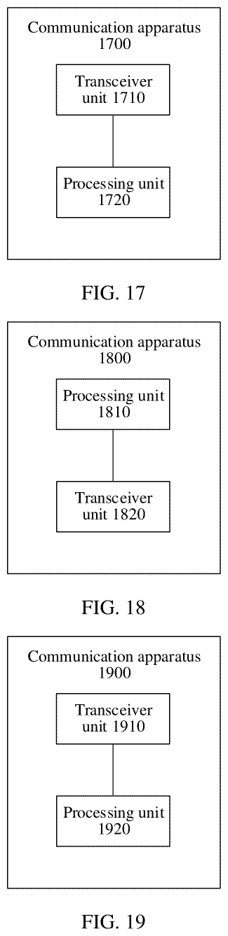

FIG. 17 is a schematic block diagram of another communication apparatus 1700 according to an embodiment of this application. The apparatus may be used in the second device in the method embodiment in FIG. 9. The communication apparatus 1700 includes:
a transceiver unit 1710, configured to receive encoded data; and a processing unit, configured to determine a target lifting size based on a length of an information bit corresponding to the encoded data, an information column quantity of an LDPC base graph, and n bases, where the target lifting size is in a plurality of lifting sizes corresponding to the n bases, a lifting size corresponding to an i^{th} base aᵢ in the n bases is aᵢ×2^{k}^{ᵢ}, aᵢ is a positive integer, and kᵢ is an integer greater than or equal to zero.

The processing unit 1720 is further configured to determine a first shifting value set corresponding to the target lifting size, where the first shifting value set is in n shifting value sets, the n shifting value sets are in one-to-one correspondence with the n bases, an i^{th} shifting value set in the n shifting value sets belongs to {tᵢ,1+tᵢ,2+tᵢ, . . . , Uᵢ+tᵢ−1}, Uᵢ is less than or equal to a second preset threshold, t is an integer, and Uᵢ is a positive integer.

The processing unit 1720 is further configured to decode the encoded data based on the target lifting size and the first shifting value set.

Optionally, the processing unit 1720 is specifically configured to: determine, based on the length of the information bit corresponding to the encoded data, the information column quantity of the LDPC base graph, and the n bases, n candidate lifting sizes corresponding to the n bases, where lengths of information bits of LDPC codes corresponding to the n candidate lifting sizes are greater than or equal to the length of the information bit corresponding to the to-be-transmitted data; and determine a smallest candidate lifting size in the n candidate lifting sizes as the target lifting size.

Optionally, the processing unit 1720 is specifically configured to determine the target lifting size based on the length of the information bit corresponding to the encoded data, the information column quantity of the LDPC base graph, the n bases, and a lifting size threshold.

Optionally, the processing unit 1720 is specifically configured to: determine, based on the length of the information bit corresponding to the encoded data, the information column quantity of the LDPC base graph, and the n bases, n candidate lifting sizes corresponding to the n bases, where lengths of information bits of LDPC codes corresponding to the n candidate lifting sizes are greater than or equal to the length of the information bit corresponding to the to-be-transmitted data; and if a smallest candidate lifting size in the n candidate lifting sizes is less than or equal to the lifting size threshold, determine the smallest candidate lifting size as the target lifting size; or if the smallest candidate lifting size in the n candidate lifting sizes is greater than the lifting size threshold, determine the lifting size threshold as the target lifting size.

Optionally, a difference between different Uᵢ corresponding to the n shifting value sets is less than or equal to a third preset threshold.

Optionally, the transceiver unit 1710 is further configured to receive indication information, where the indication information indicates the target lifting size and/or the first shifting value set.

FIG. 18 is a schematic block diagram of another communication apparatus 1800 according to an embodiment of this application. The apparatus may be used in the first device in the method embodiment in FIG. 12. The communication apparatus 1800 includes:
a processing unit 1810, configured to determine a plurality of bases based on a length of an information bit corresponding to to-be-transmitted data, an information column quantity of an LDPC base graph, and a plurality of first coefficients, where the plurality of bases are used to determine a plurality of lifting sizes, the plurality of lifting sizes are in one-to-one correspondence with the plurality of bases and the plurality of first coefficients, a first lifting size in the plurality of lifting sizes is equal to a product of a first basis corresponding to the first lifting size and the first coefficient corresponding to the first lifting size, the first base is in the plurality of bases, and the plurality of bases and the plurality of first coefficients are positive integers, where
the processing unit 1810 is further configured to determine a target lifting size from the plurality of lifting sizes based on a threshold of a quantity of shortened bits; and
a transceiver unit 1820, configured to send the to-be-transmitted data based on the target lifting size and a shifting value set corresponding to the target lifting size.

Optionally, the processing unit 1810 is specifically configured to: if a difference between a code length of an LDPC code corresponding to at least one of the plurality of lifting sizes and the length of the information bit is less than or equal to the threshold of the quantity of shortened bits, determine the target lifting size from the at least one lifting size, where a value of the first coefficient corresponding to the target lifting size is the largest; or if a difference between a code length of an LDPC code corresponding to each of the plurality of lifting sizes and the length of the information bit is greater than the threshold of the quantity of shortened bits, determine, as the target lifting size, a lifting size in the plurality of lifting sizes that corresponds to an LDPC code whose code length has a minimum difference from the length of the information bit.

Optionally, a set of the plurality of first coefficients belongs to {2, 4, 8, 16, . . . , 2^{N}} where N is an integer greater than 1.

Optionally, the transceiver unit 1820 is further configured to send indication information, where the indication information indicates the target lifting size and/or the shifting value set corresponding to the target lifting size.

FIG. 19 is a schematic block diagram of a communication apparatus 1900 according to an embodiment of this application. The apparatus may be used in the second device in the method embodiment in FIG. 12. The communication apparatus 1900 includes:
a transceiver unit 1910, configured to receive encoded data; and
a processing unit 1920, configured to determine a plurality of bases based on a length of an information bit corresponding to the encoded data, an information column quantity of an LDPC base graph, and a plurality of first coefficients, where the plurality of bases are used to determine a plurality of lifting sizes, the plurality of lifting sizes are in one-to-one correspondence with the plurality of bases and the plurality of first coefficients, a first lifting size in the plurality of lifting sizes is equal to a product of a first basis corresponding to the first lifting size and the first coefficient corresponding to the first lifting size, the first base is in the plurality of bases, and the plurality of bases and the plurality of first coefficients are positive integers.

The processing unit 1920 is further configured to determine a target lifting size from the plurality of lifting sizes based on a threshold of a quantity of shortened bits.

The processing unit 1920 is further configured to decode the encoded data based on the target lifting size and a shifting value set corresponding to the target lifting size.

Optionally, the processing unit 1920 is specifically configured to: if a difference between a code length of an LDPC code corresponding to at least one of the plurality of lifting sizes and the length of the information bit is less than or equal to the threshold of the quantity of shortened bits, determine the target lifting size from the at least one lifting size, where a value of the first coefficient corresponding to the target lifting size is the largest; or if a difference between a code length of an LDPC code corresponding to each of the plurality of lifting sizes and the length of the information bit is greater than the threshold of the quantity of shortened bits, determine, as the target lifting size, a lifting size in the plurality of lifting sizes that corresponds to an LDPC code whose code length has a minimum difference from the length of the information bit.

Optionally, a set of the plurality of first coefficients belongs to {2, 4, 8, 16, . . . , 2^{N}} where N is an integer greater than 1.

Optionally, the transceiver unit 1910 is further configured to receive indication information, where the indication information indicates the target lifting size and/or the shifting value set corresponding to the target lifting size.

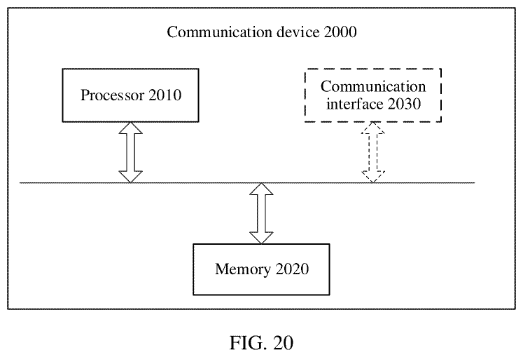

An embodiment of this application provides a communication device 2000. FIG. 20 is a schematic block diagram of the communication device 2000 according to an embodiment of this application.

The communication device 2000 includes a processor 2010, a memory 2020, and a communication interface 2030.

The memory 2020 is configured to store a computer program.

The processor 2010 is coupled to the memory 2020 by using the communication interface 2030. The processor 2010 is configured to invoke and run the computer program in the memory 2020, so that the method in embodiments of this application is performed. The communication device may be the first device or the second device in embodiments of this application. Optionally, the processor 2010 and the memory 2020 are integrated together.

The processor 2010 may be an integrated circuit chip and has a signal processing capability. In an implementation process, the steps in the foregoing method embodiments may be implemented by using a hardware integrated logic circuit in the processor or by using instructions in a form of software. The foregoing processor may be a general-purpose processor, a digital signal processor (digital signal processor, DSP), an application-specific integrated circuit (application-specific integrated circuit, ASIC), a field programmable gate array (field programmable gate array, FPGA) or another programmable logic device, a discrete gate or transistor logic device, or a discrete hardware component. The processor can implement or perform the methods, the steps, and the logical block diagrams that are disclosed in embodiments of this application. The general-purpose processor may be a microprocessor, or the processor may be any conventional processor or the like. The steps in the methods disclosed with reference to embodiments of this application may be directly performed and completed by a hardware decoding processor, or may be performed and completed by using a combination of hardware in the decoding processor and a software module. The software module may be located in a mature storage medium in the art, such as a random access memory, a flash memory, a read-only memory, a programmable read-only memory, an electrically erasable programmable memory, or a register. The storage medium is located in the memory, and the processor reads information in the memory and completes the steps in the foregoing methods in combination with the hardware in the processor.

Optionally, an embodiment of this application further provides a communication device. The communication device includes an input/output interface and a logic circuit. The input/output interface is configured to obtain input information and/or output information. The logic circuit is configured to perform the method in any one of the foregoing method embodiments, to perform processing and/or generate the output information based on the input information.

An embodiment of this application further provides a communication system. The communication system includes the first device and the second device in any one of the foregoing method embodiments. Alternatively, the communication system includes the communication apparatus in FIG. 14, FIG. 16, or FIG. 18, and the communication apparatus in FIG. 15, FIG. 17, or FIG. 19.

An embodiment of this application further provides a computer-readable storage medium. The computer-readable storage medium stores a computer program used to implement the methods in the foregoing method embodiments. When the computer program runs on a computer, the computer is enabled to implement the methods in the foregoing method embodiments.

An embodiment of this application further provides a computer program product. The computer program product includes computer program code. When the computer program code is run on a computer, the methods in the foregoing method embodiments are performed.

An embodiment of this application further provides a chip, including a processor. The processor is coupled to a memory. The memory is configured to store a computer program, and the processor is configured to execute the computer program stored in the memory, so that the chip implements the methods in the foregoing method embodiments.

It should be understood that in embodiments of this application, numbers “first”, “second”, and the like are merely for distinguishing between different objects, for example, for distinguishing between different devices or different preset thresholds, and do not constitute a limitation on the scope of embodiments of this application. Embodiments of this application are not limited thereto.

In addition, the term “and/or” in this application describes only an association relationship for describing associated objects and indicates that three relationships may exist. For example, “A and/or B” may indicate the following three cases: Only A exists, both A and B exist, and only B exists. In addition, the character “/” in this specification usually indicates an “or” relationship between the associated objects. In this application, the term “at least one” may indicate “one” and “two or more”. For example, at least one of A, B, and C may indicate the following seventh cases: Only A exists, only B exists, only C exists, both A and B exist, both A and C exist, both C and B exist, and A, B, and C all exist.

A person of ordinary skill in the art may be aware that, the units and the algorithm steps in the examples described with reference to the embodiments disclosed in this specification can be implemented by electronic hardware or a combination of computer software and electronic hardware. Whether the functions are performed by hardware or software depends on particular applications and design constraint conditions of the technical solutions. A person skilled in the art may use different methods to implement the described functions for each specific application, but such implementation should not be considered beyond the scope of this application.

It may be clearly understood by a person skilled in the art that, for the purpose of convenient and brief description, for detailed working processes of the foregoing systems, apparatuses, and units, refer to corresponding processes in the foregoing method embodiments. Details are not described herein again.

In the several embodiments provided in this application, it should be understood that the disclosed system, apparatus, and method may be implemented in other manners. For example, the apparatus embodiments described above are merely examples. For example, division into the units is merely logical function division, and there may be another division manner during actual implementation. For example, a plurality of units or components may be combined or integrated into another system, or some features may be ignored or not performed. In addition, the displayed or discussed mutual couplings or direct couplings or communication connections may be implemented by using some interfaces. The indirect couplings or communication connections between the apparatuses or units may be implemented in an electrical form, a mechanical form, or another form.

The units described as separate parts may or may not be physically separate, and parts displayed as units may or may not be physical units, that is, may be located in one place, or may be distributed on a plurality of network units. Some or all of the units may be selected based on actual requirements to achieve the objectives of the solutions of embodiments.

In addition, functional units in embodiments of this application may be integrated into one processing unit, each of the units may exist alone physically, or two or more units may be integrated into one unit.

When the function is implemented in a form of a software functional unit and sold or used as an independent product, the function may be stored in a computer-readable storage medium. Based on such an understanding, the technical solutions in this application essentially, or the part contributing to the conventional technology, or some of the technical solutions may be implemented in a form of a software product. The computer software product is stored in a storage medium and includes several instructions for instructing a computer device (which may be a personal computer, a server, a network device, or the like) to perform all or some of the steps in the methods in embodiments of this application. The foregoing storage medium includes any medium that can store program code, such as a USB flash drive, a removable hard disk, a read-only memory (read-only memory, ROM), a random access memory (random access memory, RAM), a magnetic disk, or an optical disc.

The foregoing descriptions are merely specific implementations of this application, but are not intended to limit the protection scope of this application. Any variation or replacement readily figured out by a person skilled in the art within the technical scope disclosed in this application shall fall within the protection scope of this application. Therefore, the protection scope of this application shall be subject to the protection scope of the claims.

1. A data transmission method, comprising:
determining a target lifting size based on a length of an information bit corresponding to to-be-transmitted data and an information column quantity of a low-density parity-check code LDPC base graph, wherein the target lifting size is in at least one of m lifting size sets, one lifting size set comprises a lifting size corresponding to at least one of n bases, the m lifting size sets comprise lifting sizes corresponding to the n bases, a lifting size corresponding to an i^{th} base aᵢ in the n bases is determined based on a product of aᵢ and an integer power of 2, n is greater than m, and aᵢ is a positive integer;
determining a first shifting value set corresponding to the target lifting size, wherein the first shifting value set is in m shifting value sets; and
sending the to-be-transmitted data based on the target lifting size and the first shifting value set.

2. The method according to claim 1, wherein
the m shifting value sets are in one-to-one correspondence with the m lifting size sets.

3. The method according to claim 1, wherein
a j^{th} shifting value set in the m shifting value sets belongs to {tⱼ,1+tⱼ,2+tⱼ, . . . , H₍ⱼ₎+tⱼ−1}, H₍ⱼ₎ is less than a maximum value of lifting sizes in a j^{th} lifting size set corresponding to the j^{th} shifting value set, tⱼ is an integer, and H₍ⱼ₎ is a positive integer.

4. The method according to claim 3, wherein
a difference between different H₍ⱼ₎ corresponding to the m shifting value sets is less than or equal to a first preset threshold.

5. The method according to claim 1, wherein the method further comprises:
sending indication information, wherein the indication information indicates the target lifting size and/or the first shifting value set.

6. A data transmission method, comprising:
receiving encoded data;
determining a target lifting size based on a length of an information bit corresponding to the encoded data and an information column quantity of an LDPC base graph, wherein the target lifting size is in at least one of m lifting size sets, one lifting size set comprises a lifting size corresponding to at least one of n bases, the m lifting size sets comprise lifting sizes corresponding to the n bases, a lifting size corresponding to an i^{th} base aᵢ in the n bases is determined based on a product of aᵢ and an integer power of 2, n is greater than m, and aᵢ is a positive integer;
determining a first shifting value set corresponding to the target lifting size, wherein the first shifting value set is in m shifting value sets; and
decoding the encoded data based on the target lifting size and the first shifting value set.

7. The method according to claim 6, wherein
the m shifting value sets are in one-to-one correspondence with the m lifting size sets.

8. The method according to claim 6, wherein
a j^{th} shifting value set in the m shifting value sets belongs to {tⱼ,1+tⱼ,2+tⱼ, . . . , Hⱼ+tⱼ−1}, H₍ⱼ₎ is less than a maximum value of lifting sizes in a j^{th} lifting size set corresponding to the j^{th} shifting value set, tⱼ is an integer, and H₍ⱼ₎ is a positive integer.

9. The method according to claim 8, wherein
a difference between different H₍ⱼ₎ corresponding to the m shifting value sets is less than or equal to a first preset threshold.

10. The method according to claim 6, wherein the method further comprises:
receiving indication information, wherein the indication information indicates the target lifting size and/or the first shifting value set.

11. A communication apparatus, comprising:
a processing unit, configured to determine a target lifting size based on a length of an information bit corresponding to to-be-transmitted data and an information column quantity of a low-density parity-check code LDPC base graph, wherein the target lifting size is in at least one of m lifting size sets, one lifting size set comprises a lifting size corresponding to at least one of n bases, the m lifting size sets comprise lifting sizes corresponding to the n bases, a lifting size corresponding to an i^{th} base aᵢ in the n bases is determined based on a product of aᵢ and an integer power of 2, n is greater than m, and aᵢ is a positive integer, wherein
the processing unit is further configured to determine a first shifting value set corresponding to the target lifting size, wherein the first shifting value set is in m shifting value sets; and
a transceiver unit, configured to send the to-be-transmitted data based on the target lifting size and the first shifting value set.

12. The apparatus according to claim 11, wherein
the m shifting value sets are in one-to-one correspondence with the m lifting size sets.

13. The apparatus according to claim 11, wherein
a j^{th} shifting value set in the m shifting value sets belongs to {tⱼ,1+tⱼ,2+tⱼ, . . . , H₍ⱼ₎+tⱼ−1}, H₍ⱼ₎ is less than a maximum value of lifting sizes in a j^{th} lifting size set corresponding to the j^{th} shifting value set, tⱼ is an integer, and H₍ⱼ₎ is a positive integer.

14. The apparatus according to claim 13, wherein
a difference between different H₍ⱼ₎ corresponding to the m shifting value sets is less than or equal to a first preset threshold.

15. The apparatus according to claim 11, wherein
the transceiver unit is further configured to send indication information, wherein the indication information indicates the target lifting size and/or the first shifting value set.
